(19) United States
(12) Patent Application Publication
(10) Pub. No.: US 2024/0235744 A1
(43) Pub. Date: Jul. 11, 2024

(54) METHODS AND APPRATUSES FOR WIRELESS COMMUNICATION RETRANSMISSION USING CHECK BLOCKS GENERATED ACCORDING TO SUBBLOCK INTERLEAVERS

(71) Applicant: HUAWEI TECHNOLOGIES CO., LTD., Shenzhen (CN)

(72) Inventors: Yu CAO, Kanata (CA); Ming JIA, Kanata (CA); Jianglei MA, Kanata (CA)

(21) Appl. No.: 18/616,490

(22) Filed: Mar. 26, 2024

Related U.S. Application Data
(63) Continuation of application No. PCT/CN2021/121483, filed on Sep. 28, 2021.

(51) Int. Cl. H04L 1/1812; H04L 1/00

(52) U.S. Cl. CPC H04L 1/1819; H04L 1/0061; H04L 1/0071

(57) ABSTRACT

Methods and systems for wireless communications by performing HARQ-based retransmissions using vertical check blocks are described. After performing an initial transmission, a first retransmission is performed. The first retransmission includes at least one vertical check block from a first set of vertical check blocks generated using a first subblock interleaver set associated with a first RV index of the first retransmission. A second retransmission is performed, including at least one vertical check block from a second set of vertical check blocks generated using a second subblock interleaver set associated with a second RV index of the second retransmission.

### RELATED APPLICATION

This application is a continuation of International Application No. PCT/CN2021/121483, filed on Sep. 28, 2021, the disclosure of which is hereby incorporated by reference in its entirety.

### FIELD

The present disclosure relates to wireless communications, including a redundancy version-based retransmission scheme using subblock interleavers for check block generation.

### BACKGROUND

Hybrid automatic repeat request (HARQ) is a common technique used in wireless communications for retransmission. HARQ enables reliability of wireless transmissions to be increased, while incurring lower latency compared to automatic repeat request (ARQ). In Long Term Evolution (LTE), a transport block (TB) scheduled by the scheduler can be divided into several forward error correction (FEC)-encoded blocks. HARQ retransmission, however, is TB based. If one TB transmission fails (e.g., via CRC check), the redundant versions of all the FEC-encoded blocks will have to be retransmitted, even though some of the FEC-encoded blocks may have been correctly received. The retransmission can be done using the same or different redundancy version (RV) of the same TB. Soft combining of the different (re)transmissions of the same TB can be used for recovering the TB at the receiving node.

In New Radio (NR) release 15 (i.e., the “5G” standard specification), code block group (CBG)-based retransmission is supported, where a group of code blocks is a group of FEC-encoded blocks (which may be a subset of the FEC-encoded blocks in a TB). The difference between CBG-based HARQ in NR and TB-based HARQ in LTE is that CBG-based HARQ in NR allows retransmitting of one or multiple CBGs instead of the whole TB. Therefore, if feedback from a receiving node indicates that some of the CBGs have already been recovered (i.e., decoded) successfully, the already recovered CBGs do not need to be retransmitted. However, for CBG-based retransmission, the receiving node needs to feedback the CBG index that was not successfully recovered (and thus needs to be retransmitted), which increases the overhead of HARQ feedback. Thus, it is desirable to provide a solution for CBG-based HARQ retransmission that incurs less overhead.

### SUMMARY

The present disclosure describes methods and apparatuses for performing HARQ-based retransmissions using vertical check blocks. A vertical check block contains check bits generated from information bits that are selected across multiple information code blocks. The vertical check block can be used, together with soft information from previous decoding attempt(s), to help recover information CBs.

In examples described herein, the set of vertical check blocks that is used for performing a given retransmission is generated using a particular subblock interleaver set, in which each subblock interleaver set is uniquely mapped to a respective redundancy version index. The association between each subblock interleaver set and a respective redundancy version index is defined, and known to both the transmitting node and the receiving node. In this way, only the redundancy version index of the given retransmission needs to be communicated to the receiving node to enable the receiving node to make use of the vertical check blocks received in the given retransmission.

In various examples, the present disclosure describes various techniques that may be used to define subblock interleaver sets according to the redundancy version index. In some examples, subblock interleaver sets that are defined using such techniques may be computed as needed by the transmitting node and/or receiving node, based on the redundancy version index of a given retransmission. In other examples, the subblock interleaver sets may be computed ahead of time and stored in tables (the tables may be defined in a standard), and simply retrieved from memory as needed.

In an example aspect, the present disclosure describes a method, including: performing an initial transmission, including transmitting a transport block comprising two or more information code blocks (CBs) to a receiving node; performing a first retransmission to the receiving node, including transmitting at least one check block from a first set of one or more check blocks, the at least one check block generated from at least part of each of the two or more information CBs, the first set of one or more check blocks generated using a first subblock interleaver associated with a first redundancy version (RV) index of the first retransmission; and performing a second retransmission to the receiving node, including transmitting at least one check block from a second set of one or more check blocks generated using a second subblock interleaver associated with a second RV index of the second retransmission.

In the preceding example aspect of the method, the method may further include: prior to performing the initial transmission, providing to the receiving node an RV index of the initial transmission; and providing the first RV index of the first retransmission and the second RV index of the second retransmission to the receiving node prior to performing the first retransmission and prior to performing the second retransmission, respectively.

In the preceding example aspect of the method, the RV index of the initial transmission, the first RV index of the first retransmission and the second RV index of the second retransmission may be provided together in a control signal or configuration signal to the receiving node prior to performing the initial transmission.

In any of the preceding example aspects of the method, feedback from the receiving node may indicate whether the receiving node successfully decoded the two or more information CBs. The method may further include: performing the first retransmission after determining, from received negative acknowledgement (NACK) feedback or absence of acknowledgement (ACK) feedback, that the receiving node failed to successfully decode the two or more information CBs after the initial transmission; and performing the second retransmission after determining, from received NACK feedback or absence of ACK feedback, that the receiving node failed to successfully decode the two or more information CBs after the first retransmission.

In any of the preceding example aspects of the method, a predetermined number of retransmissions, including the first and second retransmissions, may be performed without requiring any feedback from the receiving node.

In any of the preceding example aspects of the method, the first subblock interleaver set may include a first plurality of subblock interleavers, wherein each subblock interleaver in the first subblock interleaver set applies a respective amount of cyclic shift to subblocks of a respective information CB to obtain a first interleaved subblock combination; and where the second subblock interleaver set may include a second plurality of subblock interleavers, wherein each subblock interleaver in the second subblock interleaver applies a respective amount of cyclic shift to subblocks of a respective information CB to obtain a second interleaved subblock combination.

In any of the preceding example aspects of the method, and a difference in the amount of cyclic shift applied by any two subblock interleavers in the first subblock interleaver set to the subblocks of respective two information CBs may not be equal to the difference in the amount of cyclic shift applied by any two subblock interleavers in the second subblock interleaver set applied to the subblocks of the same two information CBs.

In any of the preceding example aspects of the method, the first subblock interleaver set may be defined based on the first RV index and the second subblock interleaver set may be defined based on the second RV index.

In the preceding example aspect of the method, each of the first and second subblock interleavers may be defined to apply an amount of cyclic shift to subblocks of each information CB wherein the amount of cyclic shift is a function of (j+c₁)*(i+c₂), where j is the first or second RV index of the first or second retransmission, respectively, i is an index of the information CB, and c₁ and c₂ are each integer constants.

In any of the preceding example aspects of the method, each information CB may be logically divided into K subblocks, where there are K check blocks in each of the first set and second set of check blocks.

In the preceding example aspect of the method, K may be a smallest prime number that is equal to or greater than the number of information CBs in the TB.

In a preceding example aspect of the method, the first or the second subblock interleaver may be defined to apply an amount of cyclic shift to subblocks of each information CB that is a function of (j+c₁)*(i+c₂) mode (K−L), where j is the first or second RV index of the first or second retransmission, respectively, i is an index of the information CB, c₁ and c₂ are each integer constants, K is equal to the number of information CBs in the TB, and (K−L) is a prime number.

In a preceding example aspect of the method, each of the first and second subblock interleaver sets may be defined to apply an amount of cyclic shift to subblocks of each information CB according to the formula:

$$( j - 1 ) * ( i - 1 ) mod K$$

where j is the first or second RV index of the first or second retransmission, respectively, i is an index of the information CB, K is equal to the number of information CBs in the TB, and (j−1) and K are coprime.

In a preceding example aspect of the method, each of the first and second subblock interleaver sets may be defined to apply an amount of cyclic shift to subblocks of each information CB, wherein no cyclic shift is applied to an information CB that is a reference row of the TB and the amount of cyclic shift applied to subblocks of other information CBs by the second subblock interleaver set is obtained by vertical cyclic shifting of the amount of cyclic shift applied to subblocks of corresponding information CBs by the first subblock interleaver set.

In any of the preceding example aspects of the method, the first RV index and the second RV index may be non-consecutive integers.

In any of the preceding example aspects of the method, a first number of retransmissions may be performed using a first group of subblock interleaver sets, and an additional number of retransmissions may be performed using an additional group of subblock interleaver sets.

In the preceding example aspect of the method, the first group of subblock interleaver sets may interleave the information CBs of the TB by splitting each information CB into a first number of subblocks, and the second group of subblock interleaver sets may interleave the information CBs by splitting each information CB into a second number of subblocks.

In the preceding example aspect of the method, the first number of subblocks may be a first prime number and the second number of subblocks may be a second prime number that is a next higher prime number after the first prime number.

In a preceding example aspect of the method, the first group of subblock interleaver sets may interleave the information CBs of the TB by applying cyclic shifting to each information CB, and the second group of subblock interleaver sets may interleave the information CBs by applying a non-cyclic shift shuffling to at least one information CB to create an alternate base subblock combination and further applying cyclic shifting to the alternate base subblock combination.

In any of the preceding example aspects of the method, the first and second subblock interleaver sets may be predefined for the first and second RV indices, respectively.

In an example aspect, the present disclosure describes an apparatus including a processing unit. The processing unit is configured to execute machine-readable instructions to cause the apparatus to: perform an initial transmission, including transmitting a transport block comprising two or more information code blocks (CBs) to a receiving node; perform a first retransmission to the receiving node, including transmitting at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and perform a second retransmission to the receiving node, including transmitting at least one check block from a second set of one or more check blocks generated using a second subblock interleaver set associated with a second RV index of the second retransmission.

In the preceding example aspect of the apparatus, the processing unit may be further configured to execute instructions to cause the apparatus to perform any of the preceding example aspects of the method.

In an example aspect, the present disclosure describes a computer readable medium having machine-executable instructions stored thereon. The instructions, when executed by a processing unit of an apparatus, cause the apparatus to: perform an initial transmission, including transmitting a transport block comprising two or more information code blocks (CBs) to a receiving node; perform a first retransmission to the receiving node, including transmitting at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and perform a second retransmission to the receiving node, including transmitting at least one check block from a second set of one or more check blocks generated using a second subblock interleaver set associated with a second RV index of the second retransmission.

In the preceding example aspect of the computer readable medium, the instructions may further cause the apparatus to perform any of the preceding example aspects of the method.

In an example aspect, the present disclosure describes a method, including: receiving an initial transmission from a transmitting node, including a transport block comprising two or more information code blocks (CBs); receiving a first retransmission from the transmitting node, including at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and receiving a second retransmission from the transmitting node, including at least one check block from a second set of one or more check blocks generated using a second subblock interleaver set associated with a second RV index of the second retransmission.

In the preceding example aspect of the method, the method may further include: prior to receiving the initial transmission, receiving an RV index of the initial transmission; receiving the first RV index of the first retransmission and the second RV index of the second retransmission prior to receiving the first retransmission and prior to receiving the second retransmission, respectively; and determining the first subblock interleaver set and the second subblock interleaver set using the first RV index and the second RV index, respectively.

In the preceding example aspect of the method, the RV index of the initial transmission, the first RV index of the first retransmission and the second RV index of the second retransmission may be received together in a control signal or configuration signal prior to receiving the initial transmission.

In any of the preceding example aspects of the method, the method may further include: after the initial transmission, transmitting to the transmitting node a first indicator that the two or more information CBs were not all successfully decoded, wherein the first retransmission is received subsequent to transmitting the first indicator; and after the first retransmission, transmitting to the transmitting node a second indicator that the two or more information CBs were not all successfully decoded, wherein the second retransmission is received subsequent to transmitting the second indicator.

In any of the preceding example aspects of the method, a predetermined number of retransmissions, including the first and second retransmissions, may be scheduled.

In any of the preceding example aspects of the method, the first and second subblock interleaver sets may be predefined for the first and second RV indices, respectively.

In an example aspect, the present disclosure describes an apparatus including a processing unit. The processing unit is configured to execute machine-readable instructions to cause the apparatus to: receive an initial transmission from a transmitting node, including a transport block comprising two or more information code blocks (CBs); receive a first retransmission from the transmitting node, including at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and receive a second retransmission from the transmitting node, including at least one check block from a second set of one or more check blocks generated using a second subblock interleaver set associated with a second RV index of the second retransmission.

In the preceding example aspect of the apparatus, the processing unit may be further configured to execute instructions to cause the apparatus to perform any of the preceding example aspects of the method.

In an example aspect, the present disclosure describes a computer readable medium having machine-executable instructions stored thereon. The instructions, when executed by a processing unit of an apparatus, cause the apparatus to: receive an initial transmission from a transmitting node, including a transport block comprising two or more information code blocks (CBs); receive a first retransmission from the transmitting node, including at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and receive a second retransmission from the transmitting node, including at least one check block from a second set of one or more check blocks generated using a second subblock interleaver set associated with a second RV index of the second retransmission.

In the preceding example aspect of the computer readable medium, the instructions, when executed by a processing unit of an apparatus, may cause the apparatus to perform the any of the aspects of the method described above.

### BRIEF DESCRIPTION OF THE DRAWINGS

Reference will now be made, by way of example, to the accompanying drawings which show example embodiments of the present application, and in which:

FIG. 1 is a schematic diagram of an example wireless communication system suitable for implementing examples described herein;

FIGS. 2 and 3 are block diagrams showing example apparatuses suitable for implementing examples described herein;

FIGS. 4A and 4B illustrate example code structures for a single transport block (TB), including horizontal check blocks and vertical check blocks;

FIG. 5 illustrates an example code structure for a single TB based on non-systematic code, including vertical check blocks;

FIG. 6 illustrates an example code structure for generating vertical check blocks, illustrating how information bits are logically split into subblocks;

FIGS. 7A and 7B are signaling diagrams illustrating examples of using vertical check blocks for retransmissions, in accordance with examples disclosed herein;

FIGS. 8A and 8B are flowcharts illustrating example methods that may be performed by a transmitting node or a receiving node, respectively, in accordance with FIGS. 7A and 7B;

FIG. 9A illustrates an example of using a subblock interleaver set to generate a set of vertical check blocks;

FIG. 9B illustrates examples of left and right cyclic shifting applied to a row of subblocks;

FIG. 10 illustrates an example of using different subblock interleaver sets to obtain different subblock combinations for different RV indices, in accordance with examples disclosed herein;

FIG. 11A illustrates an example set of subblock combinations that may be obtained using a group of subblock interleaver sets defined using a prime number-based cyclic shifting technique disclosed herein;

FIG. 11B illustrates another example set of subblock combinations that may be obtained using a group of subblock interleaver sets defined using a prime number-based cyclic shifting technique disclosed herein;

FIG. 12 illustrates two subblock combinations, to assist in understanding the prime number-based cyclic shifting technique disclosed herein;

FIG. 13 illustrates an example set of subblock combinations that may be obtained using a group of subblock interleaver sets defined using a dual subblock-based cyclic shifting technique disclosed herein;

FIG. 14 illustrates an example set of subblock combinations that may be obtained using a group of subblock interleaver sets defined using a prime factor-based cyclic shifting technique disclosed herein;

FIG. 15 illustrates an example set of subblock combinations that may be obtained using a group of subblock interleaver sets defined using a RV index skipping technique disclosed herein;

FIG. 16 illustrates an example set of subblock combinations that may be obtained using a group of subblock interleaver sets defined using the prime number-based cyclic shifting technique, where additional subblock combinations are obtained by increasing the number of subblocks, in accordance with examples disclosed herein; and

FIG. 17 illustrates an example set of subblock combinations that may be obtained using a group of subblock interleaver sets defined using the prime number-based cyclic shifting technique, where additional subblock combinations are obtained by creating an alternate based subblock combination, in accordance with examples disclosed herein.

Similar reference numerals may have been used in different figures to denote similar components.

### DESCRIPTION OF EXAMPLE EMBODIMENTS

In various examples described herein, methods and apparatuses for generating vertical check blocks for HARQ-based retransmission are described. The examples described herein enable vertical check blocks to be generated using different subblock interleaver sets that are associated with respective different redundancy version (RV) indices, such that the subblock interleaver set used for a given retransmission can be determined by the receiving node using only the redundancy version index of the retransmission. Because the retransmission scheme includes check blocks across at least multiple information blocks (i.e., vertical check blocks) as well as check blocks on respective information blocks (i.e., horizontal check blocks), the retransmission scheme is referred to herein as a “2D” HARQ retransmission scheme for convenience and in a non-limiting manner; other suitable names may also be used in general.

To help understand the present disclosure, some existing approaches for retransmission are now described.

Existing hybrid automatic repeat request (HARQ) retransmission schemes include feedback-based retransmission schemes and blind retransmission schemes. In feedback-based retransmission, a receiving node (or simply a receiver) may send acknowledgement (ACK) or negative acknowledgement (NACK) back to the transmitting node (or simply the transmitter). A retransmission is sent to the receiving node if a NACK is received. In blind retransmission or a repetition scheme, ACK/NACK response from the receiving node is optional. The transmitting node instead sends a predetermined number of retransmissions.

Another existing technique is erasure outer code. The erasure outer code retransmission scheme uses an erasure code to generate parity code blocks (CBs) over multiple information CBs. A Reed-Solomon code is an example of an erasure code that can be used as an outer code for generating different parity CBs for retransmission. However, when used as a rateless code, the outer code is only optimized for erasure channels. In particular, the erasure outer code approach does not utilize soft information for joint decoding (i.e., undecoded CBS are entirely discarded); therefore, the performance may suffer for non-erasure channels. As a further disadvantage, practical implementations of common erasure codes, such as Reed-Solomon and Bose-Chaudhuri-Hocquenghem codes do not work well as a rateless code. The 2D HARQ retransmission scheme described herein enables a receiving node to utilize soft information from unsuccessful decoding attempts, and therefore can achieve improved performance compared to conventional outer erasure code-based retransmission schemes.

To assist in understanding the present disclosure, an example wireless communication system is now described.

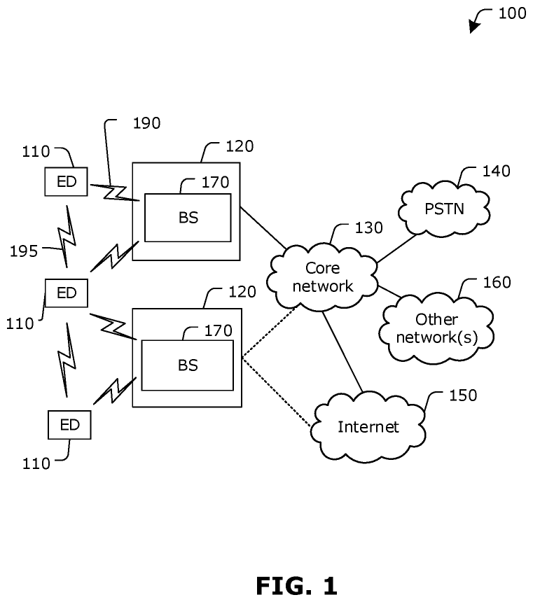

FIG. 1 illustrates an example wireless communication system 100 (also referred to as wireless system 100) in which embodiments of the present disclosure could be implemented. In general, the wireless system 100 enables multiple wireless or wired elements to communicate data and other content. The wireless system 100 may enable content (e.g., voice, data, video, text, etc.) to be communicated (e.g., via broadcast, narrowcast, user device to user device, etc.) among entities of the system 100. The wireless system 100 may operate by sharing resources such as bandwidth. The wireless system 100 may be suitable for wireless communications using 5G technology and/or later generation wireless technology. In some examples, the wireless system 100 may also accommodate some legacy wireless technology (e.g., 3G or 4G wireless technology).

In the example shown, the wireless system 100 includes electronic devices (EDs) 110, radio access networks (RANs) 120, a core network 130, a public switched telephone network (PSTN) 140, the internet 150, and other networks 160. In some examples, one or more of the networks may be omitted or replaced by a different type of network. Other networks may be included in the wireless system 100. Although certain numbers of these components or elements are shown in FIG. 1, any reasonable number of these components or elements may be included in the wireless system 100.

The EDs 110 are configured to operate, communicate, or both, in the wireless system 100. For example, the EDs 110 may be configured to transmit, receive, or both via wireless or wired communication channels. Each ED 110 represents any suitable end user device for wireless operation and may include such devices (or may be referred to) as a user equipment (UE), a wireless transmit/receive unit (WTRU), a mobile station, a mobile relay, a fixed or mobile subscriber unit, a cellular telephone, a station (STA), a machine type communication (MTC) device, a personal digital assistant (PDA), a smartphone, a laptop, a computer, a tablet, a wireless sensor, an internet of things (IoT) device, a network-enabled vehicle, or a consumer electronics device, among other possibilities. Future generation EDs 110 may be referred to using other terms.

In FIG. 1, the RANs 120 include base stations (BSs) 170. Although FIG. 1 shows each RAN 120 including a single respective BS 170, it should be understood that any given RAN 120 may include more than one BS 170, and any given RAN 120 may also include base station controller(s) (BSC), radio network controller(s) (RNC), relay nodes, elements, and/or devices. Each BS 170 is configured to wirelessly interface with one or more of the EDs 110 to enable access to any other BS 170, the core network 130, the PSTN 140, the internet 150, and/or the other networks 160. For example, the BSs 170 may also be referred to as (or include) a base transceiver station (BTS), a radio base station, a Node-B (NodeB), an evolved NodeB (eNodeB or eNB), a Home eNodeB, a gNodeB (gNB) (sometimes called a next-generation Node B), a transmission point (TP), a transmission/reception point (TRP), a site controller, an access point (AP), or a wireless router, among other possibilities. Future generation BSs 170 may be referred to using other terms. Any ED 110 may be alternatively or additionally configured to interface, access, or communicate with any other BS 170, the internet 150, the core network 130, the PSTN 140, the other networks 160, or any combination of the preceding. In some examples, a BS 170 may access the core network 130 via the internet 150.

The EDs 110 and BSs 170 are examples of communication equipment that can be used to implement some or all of the functionality and/or embodiments described herein. Any BS 170 may be a single element, as shown, or multiple elements, distributed in the corresponding RAN 120, or otherwise. Each BS 170 transmits and/or receives wireless signals within a particular geographic region or area, sometimes referred to as a “cell” or “coverage area”. A cell may be further divided into cell sectors, and a BS 170 may, for example, employ multiple transceivers to provide service to multiple sectors. In some embodiments there may be established pico or femto cells where the radio access technology supports such. A macro cell may encompass one or more smaller cells. In some embodiments, multiple transceivers could be used for each cell, for example using multiple-input multiple-output (MIMO) technology. The number of RANs 120 shown is exemplary only. Any number of RANs may be contemplated when devising the wireless system 100.

The BSs 170 communicate with one or more of the EDs 110 over one or more uplink (UL)/downlink (DL) wireless interfaces 190 (e.g., via radio frequency (RF), microwave, infrared, etc.). The UL/DL interface 190 may also be referred to as a UL/DL connection, ED-BS link/connection/interface, or ED-network link/connection/interface, for example. The EDs 110 may also communicate directly with one another (i.e., without involving the BS 170) via one or more sidelink (SL) wireless interfaces 195. The SL interface 195 may also be referred to as a SL connection, UE-to-UE link/connection/interface, vehicle-to-vehicle (V2V) link/connection/interface, vehicle-to-everything (V2X) link/connection/interface, vehicle-to-infrastructure (V2I) link/connection/interface, vehicle-to-pedestrian (V2P) link/connection/interface, ED-ED link/connection/interface, device-to-device (D2D) link/connection/interface, or simply as SL, for example. The wireless interfaces 190, 195 may utilize any suitable radio access technology. For example, the wireless system 100 may implement one or more channel access methods, such as code division multiple access (CDMA), time division multiple access (TDMA), frequency division multiple access (FDMA), orthogonal FDMA (OFDMA), or single-carrier FDMA (SC-FDMA) for wireless communications.

The RANs 120 are in communication with the core network 130 to provide the EDs 110 with various services such as voice, data, and other services. The RANs 120 and/or the core network 130 may be in direct or indirect communication with one or more other RANs (not shown), which may or may not be directly served by core network 130, and may or may not employ the same radio access technology. The core network 130 may also serve as a gateway access between (i) the RANs 120 or EDs 110 or both, and (ii) other networks (such as the PSTN 140, the internet 150, and the other networks 160). In addition, some or all of the EDs 110 may include functionality for communicating with different wireless networks over different wireless links using different wireless technologies and/or protocols. Instead of wireless communication (or in addition thereto), the EDs 110 may communicate via wired communication channels to a service provider or switch (not shown), and to the internet 150. PSTN 140 may include circuit switched telephone networks for providing plain old telephone service (POTS). The internet 150 may include a network of computers and subnets (intranets) or both, and incorporate protocols, such as Internet Protocol (IP), Transmission Control Protocol (TCP), User Datagram Protocol (UDP). The EDs 110 may be multimode devices capable of operation according to multiple radio access technologies, and incorporate multiple transceivers necessary to support such.

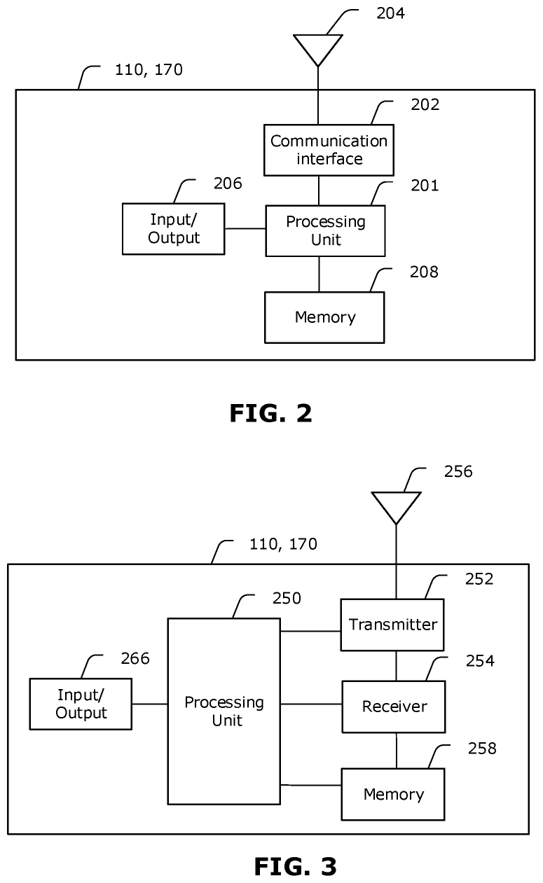

FIGS. 2 and 3 illustrate example apparatuses that may implement the methods and teachings according to this disclosure. FIGS. 2 and 3 illustrate different possible embodiments for the ED 110 and BS 170, and are not intended to be limiting.

As shown in FIG. 2, an example apparatus (e.g., an example embodiment of the ED 110 or BS 170) includes at least one processing unit 201. The processing unit 201 implements various processing operations of the apparatus. For example, the processing unit 201 could perform signal coding, data processing, power control, input/output processing, or any other functionality of the apparatus. The processing unit 201 may also be configured to implement some or all of the functionality and/or embodiments described in more detail herein. Each processing unit 201 includes any suitable processing or computing device configured to perform one or more operations. Each processing unit 201 could, for example, include a microprocessor, microcontroller, digital signal processor, field programmable gate array, or application specific integrated circuit.

The apparatus (e.g., the ED 110 or BS 170) includes at least one communication interface 202 for wired and/or wireless communications. Each communication interface 202 includes any suitable structure for generating signals for wireless or wired transmission and/or processing signals received wirelessly or by wire. The apparatus in this example includes at least one antenna 204 (in other examples, the antenna 204 may be omitted). Each antenna 204 includes any suitable structure for transmitting and/or receiving wireless or wired signals. One or multiple communication interfaces 202 could be used in the apparatus. One or multiple antennas 204 could be used in the apparatus. In some examples, one or more antennas 204 may be an antenna array 204, which may be used to perform beamforming and beam steering operations. Although shown as a single functional unit, the apparatus could also be implemented using at least one transmitter interface and at least one separate receiver interface.

The apparatus (e.g., the ED 110 or BS 170) further includes one or more input/output devices 206 or input/output interfaces (such as a wired interface to the internet 150). The input/output device(s) 206 permit interaction with a user or other devices in the network. Each input/output device 206 includes any suitable structure for providing information to or receiving information from a user, such as a speaker, microphone, keypad, keyboard, display, or touchscreen, including network interface communications.

In addition, the apparatus (e.g., the ED 110 or BS 170) includes at least one memory 208. The memory 208 stores instructions and data used, generated, or collected by the apparatus. For example, the memory 208 could store software instructions or modules configured to implement some or all of the functionality and/or embodiments described herein and that are executed by the processing unit(s) 201. Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, and the like.

As shown in FIG. 3, another example apparatus (e.g., another example embodiment of the ED 110 or BS 170) includes at least one processing unit 250, at least one transmitter 252, at least one receiver 254, one or more antennas 256, at least one memory 258, and one or more input/output devices or interfaces 266. The processing unit 250 implements various processing operations of the apparatus, such as signal coding, data processing, power control, input/output processing, or any other functionality. The processing unit 250 can also be configured to implement some or all of the functionality and/or embodiments described herein. Each processing unit 250 includes any suitable processing or computing device configured to perform one or more operations. Each processing unit 250 could, for example, include a microprocessor, microcontroller, digital signal processor, field programmable gate array, or application specific integrated circuit.

Each transmitter 252 includes any suitable structure for generating signals for wireless or wired transmission. Each receiver 254 includes any suitable structure for processing signals received wirelessly or by wire. Although shown as separate components, at least one transmitter 252 and at least one receiver 254 could be combined into a transceiver. Each antenna 256 includes any suitable structure for transmitting and/or receiving wireless or wired signals. Although a common antenna 256 is shown here as being coupled to both the transmitter 252 and the receiver 254, one or more antennas 256 could be coupled to the transmitter(s) 252, and one or more separate antennas 256 could be coupled to the receiver(s) 254. In some examples, one or more antennas 256 may be an antenna array, which may be used for beamforming and beam steering operations. Each memory 258 includes any suitable volatile and/or non-volatile storage and retrieval device(s) such as those described above with respect to FIG. 2. The memory 258 stores instructions and data used, generated, or collected by the apparatus. For example, the memory 258 could store software instructions or modules configured to implement some or all of the functionality and/or embodiments described herein and that are executed by the processing unit(s) 250.

Each input/output device/interface 266 permits interaction with a user or other devices in the network. Each input/output device/interface 266 includes any suitable structure for providing information to or receiving/providing information from a user, including network interface communications.

Techniques for joint encoding of multiple code blocks (CBs) in a single transport block (TB), including the generation of vertical check blocks, have been described in U.S. patent application Ser. No. 16/665,121, entitled “SYSTEM AND METHOD FOR HYBRID-ARQ”, filed Oct. 28, 2019, the entirety of which is hereby incorporated by reference.

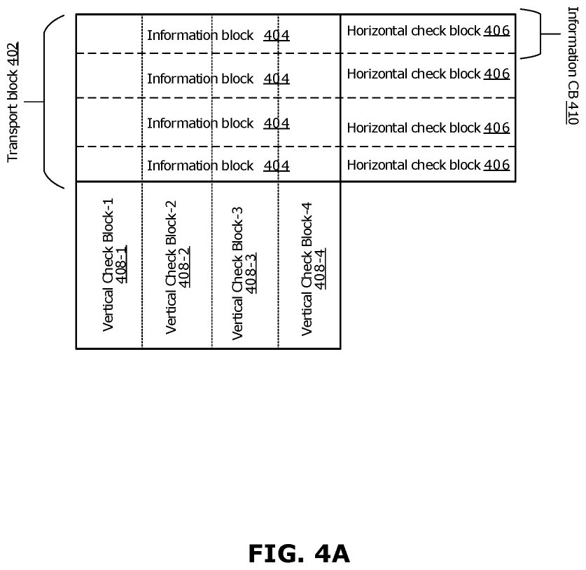

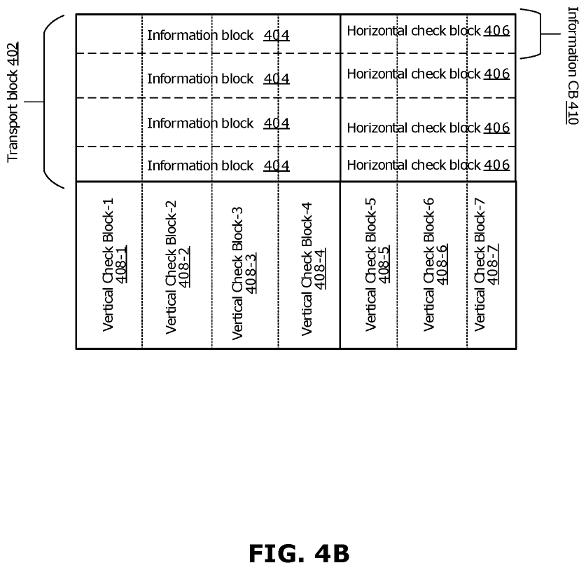

FIG. 4A illustrates an example code structure for a single TB, including horizontal check blocks and vertical check blocks. The TB 402 includes multiple information blocks 404 formed from encoder input bits (in this example, four information blocks 404 are shown for simplicity, however this is not intended to be limiting). The encoder input bits may also be referred to as information bits. The bits in this example are arranged in L rows and K columns. The code structure also includes horizontal check blocks 406 (in this example, one horizontal check block 406 for each information block 404), and vertical check blocks 1-4 408-1 to 408-4 (generally referred to as vertical check block(s) 408). In this example, four vertical check blocks 408 are shown for simplicity, however this is not intended to be limiting. The number of vertical check blocks 408 to be used may be based on configuration at the transmitting node (e.g., the BS 170 for downlink DL transmissions, or the ED 110 for uplink UL transmissions or SL transmissions) and/or defined by a standard. Further, the number of vertical check blocks 408 may or may not be equal to the number of horizontal check blocks 406. Each row in the code contains n₁ bits, including k₁ encoder input bits (or information bits) (in one information block 404) and a respective horizontal check block 406 containing n₁−k₁ check bits. In the present disclosure, check bits may also be referred to as redundancy bits, or in some examples (e.g., in the case of systematic code) referred to as parity bits.

Each information block 404 and corresponding horizontal check block 406 may be viewed as an n₁ bit information CB 410, with the TB 402 having multiple information CBs 410. In the example of FIG. 4A, the information CBs 410 are systematic CBs in that they each include systematic bits (in the information block 404) and check bits (in the horizontal check block 406) determined from the systematic bits. In other examples (discussed further below), the information CBs 410 may be non-systematic.

Each vertical check block 408 is generated from k₂ encoder input bits (or information bits) selected across multiple information blocks 404 (also referred to as cross-information block bits, cross-CB bits, or simply cross-block bits). The k₂ cross-block bits include M encoder input bits from each of the L information CBs 410, where M≥1, such that k₂=M×L. In other words, the k₂ cross-block bits include the bits from one of the K columns, and each column is M bits wide. In some examples, k₂ cross-block bits may include different numbers of information bits taken from each information CB 410. This may be expressed mathematically as: k₂=M₁+ . . . +M_{L}, where Mᵢ is the number of information bits taken from each of the L information CBs 410, Mᵢ>0 and there is no requirement for Mₚ=M_{q}, when p≠q.

In the present disclosure, reference is made to “horizontal” (as in horizontal check block 406) and to “vertical” (as in vertical check block 408). These terms are used for convenience in understanding the layout in some of the Figures, and to distinguish the two types of check blocks from each other. However, these terms are not meant to imply any physical structure. More generally, the descriptors “horizontal” and “vertical” may be equally replaced with “first” and “second”, respectively. For example, the horizontal and vertical check blocks 406, 408 can simply be referred to as first and second check blocks. In particular, each second (or vertical) check block is generated from information bits selected from two or more of the information CBs 410; therefore, the vertical check block may also be known as a cross-CB check block. The horizontal CBs may also be referred to as information CBs. For ease of understanding, the present disclosure will use the terms “horizontal” and “vertical” instead of “first” and “second”, however this is not intended to be limiting.

FIG. 4B illustrates another example code structure for a single TB, including horizontal check blocks and vertical check blocks. The example illustrated in FIG. 4B is similar to that of FIG. 4A, and features that are similar to the example of FIG. 4A need not be described again in detail. In the example of FIG. 4B, the code structure further includes vertical check blocks 5-7 408-5 to 408-7, in addition to the vertical check blocks 1-4 408-1 to 408-4 previously described (the vertical check blocks 1-7 480-1 to 408-7 may all be generally referred to as vertical check block(s) 408). The vertical check blocks 5-7 408-5 to 408-7 are similar to the vertical check blocks 1-4 408-1 to 408-4, with the difference that the vertical check blocks 5-7 408-5 to 408-7 are generated using bits selected from across multiple horizontal check blocks 406 (rather than bits selected from across multiple information blocks 404). In this way, the bits of the vertical check blocks 5-7 408-5 to 408-7 may be referred to as “check on check” bits.

FIGS. 4A and 4B show, and have been described with, bits being arranged in rows and columns; for example the vertical check block 408 is shown as having a rectangular/two dimensional structure. However, this is only for the purpose of illustration and is not intended to limit how the bits are arranged logically or in transmission. Further, the code structures shown in FIGS. 4A and 4B may be divided up for transmission. Typically all the bits of one vertical check block 408 are transmitted in the same transmission.

The check bits contained in the horizontal check blocks 406 and vertical check blocks 408 are useful to assist decoding at a receiving node. For example, after each decoding attempt at a decoder, where check bits are present, error checking can be performed to determine if the information bits in the information CB 410 have been successfully decoded. The vertical check block 408 contains check bits determined from across multiple information CBs 410, and thus provides information useful for decoding multiple information CBs 410. The decoder may use the check bits of the vertical check block 408 to assist in decoding of an information CB 410.

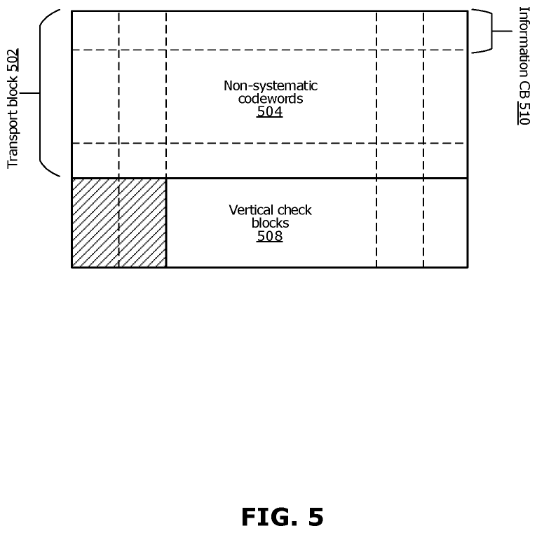

FIG. 5 illustrates an example code structure for a single TB 502 based on non-systematic code (e.g., Polar code, block code, or convolutional code). Each non-systematic codeword is determined based on a set of encoder input bits, but the information bits do not appear in the codeword as systematic bits. Unlike systematic codes, horizontal check bits cannot be simply appended at the end of each row.

The TB 502 includes multiple non-systematic codewords 504. Each non-systematic codeword 504 may be viewed as an information CB 510. Unlike the examples of FIGS. 4A and 4B, the information CB 510 does not include a distinct horizontal check block. Each vertical check block 508 is generated by one or more columns of bits taken across multiple information CBs 510, similar to that described for FIGS. 4A and 4B.

Regardless of whether the TB is based on systematic or non-systematic code, in transmission, the information CBs (transmitted with the corresponding horizontal check blocks in the case of systematic code) may be transmitted in an initial transmission. Vertical check blocks may be transmitted together with the information CBs in the initial transmission, or in a separate transmission (which may be referred to as a retransmission). Although retransmission can include just the bits from vertical check block(s), retransmission can also include some information bits related to the vertical check block(s) in the retransmission.

In examples where the information CBs are systematic (such as low density parity check (LDPC) code or Turbo code), an iterative decoding process may be used at the decoder (at the receiving node) to decode the received CBS. The decoder calculates log-likelihood ratios (LLRs) of bit values during decoding of the information CBs, which may be considered a “soft” output of the decoder. In the present disclosure, soft output may refer to decoder output that is not yet finalized (e.g., bit value not yet definitively determined to be 1 or 0 value) but may provide information that can still be useful (e.g., in a subsequent decoding iteration). Such soft output may be probabilistic in nature (e.g., LLR). Information CBs that are not correctly decoded (e.g., fails a check using the corresponding horizontal check blocks) may benefit from processing the vertical check blocks. Because each of the vertical check blocks is generated from information bits selected from two or more (or all) of the information CBS, soft output from attempts to decode a vertical check block 408 (e.g., LLR) may help to improve decoding of the information CBs (and vice versa). In at least this way, vertical check blocks help to improve decoding.

The present disclosure is not limited to systematic code, and may be equally applicable and implemented with non-systematic code. Further, although the present disclosure describe examples that use vertical check blocks in the context of unicast transmission/retransmissions (i.e., between one transmitting node and one receiving node), it should be understood that the examples described herein may also be suitable for multicast, groupcast and broadcast transmissions/retransmissions, among others.

It will be appreciated by persons skilled in the art that the following detailed discussion is not dependent on whether the vertical check blocks are generated from systematic or non-systematic CBs. For simplicity, the following may make reference to and use reference numbers referencing the examples of FIGS. 4A and 4B based on systematic CBs. It should be understood that this is not intended to be limiting.

In the present disclosure, the vertical check blocks may also be referred to as cross-block check blocks, because the bits for generating each vertical check block are taken across multiple information blocks. Similarly, the generation of the horizontal check blocks may be referred to as block-wise (or block-specific) coding, because the bits for generating each horizontal check block are taken from all the bits of a single information block. The generation of vertical check blocks may be referred to as two-dimensional (2D) coding, where 2D refers to the generation of vertical check blocks (in addition to horizontal check blocks in the case of systematic code). The use of vertical check blocks in a HARQ retransmission scheme may thus be referred to as 2D HARQ. The terms “parity block” or “redundancy block” may also be used instead of “check block”. For ease of understanding, the following discussion will refer to vertical check blocks and horizontal check blocks, however it should be understood that the terms “vertical” and “horizontal” are not intended to imply any physical structure and are not intended to be limiting.

The preceding discussion describes vertical check blocks generated from cross-block bits in a single TB. Vertical check blocks may also be generated from cross-block bits over two or more TBs (e.g., TBs sent as separate packets by a single source). This may be the case when vertical check blocks are used with network coding (e.g., as described in U.S. patent application Ser. No. 17/110,226, entitled “METHODS AND SYSTEMS FOR NETWORK CODING USING CROSS-PACKET CHECK BLOCKS”, filed Dec. 2, 2020, the entirety of which is hereby incorporated by reference). When vertical check blocks are used with network coding, a given vertical check block is generated from bits taken across two or more CBs or two or more packets (which may come from single TB or multiple TBs).

The 2D HARQ retransmission scheme, as described above, generates a vertical check block based on information bits across different information CBs. Thus, retransmission of a vertical check block can provide information to help decode multiple information CBs. At the receiving node, soft information from failed decoding attempts can be kept and combined with information from a vertical check block to help decode information CBS. Compared to conventional CBG-based HARQ schemes, the 2D HARQ retransmission scheme may not require feedback of which CBGs have been successfully recovered (and hence which CBGs require retransmission). In terms of performance, all the vertical check blocks in a retransmission provide useful information for decoding of all CBs even if some CBs have already been decoded correctly, whereas in conventional TB-based or CBG-based HARQ schemes, if some CBs have been decoded correctly, the retransmission of the corresponding CBs is not useful for decoding the undecoded CBs and hence may be considered inefficient or “wasted”.

The present disclosure describes examples that may help to reduce the redundancy and feedback required for retransmissions, compared to conventional TB or CB-group based HARQ. Examples disclosed herein may be implemented in feedback-based schemes as well as rateless code.

Although examples may be described in the context of unicast transmission, the present disclosure may be applicable to groupcast, broadcast or multicast transmissions as well. In groupcast, broadcast or multicast transmission, different receiving nodes (e.g., different UEs in the case of a DL groupcast, broadcast or multicast) may have different undecoded CBs. In such a scenario, the same vertical check block may be retransmitted to help different receiving nodes to decode different undecoded CBs, whereas in a conventional HARQ scheme, retransmitted CBs can only be used to decode that specific CB, meaning that if different CBs are undecoded for different receiving nodes, all of the different CBs have to be retransmitted. Again, this may be considered inefficient because not all of the different CBs that are retransmitted will be useful for each individual receiving node.

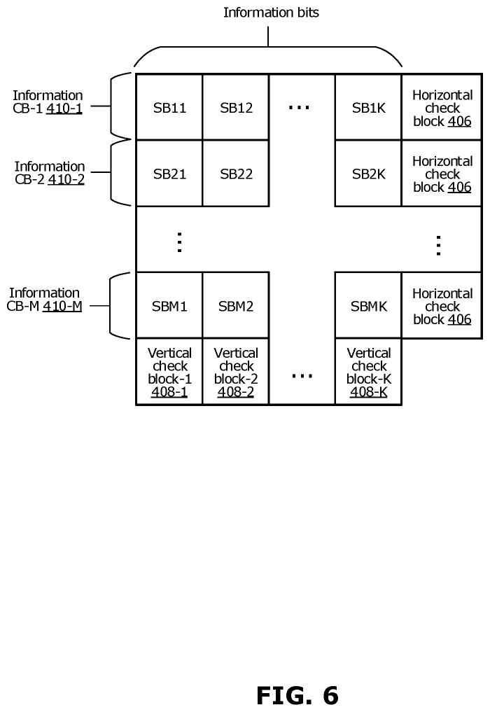

Reference is now made to FIG. 6. For simplicity, FIG. 6 illustrates an example using systematic code, however it should be understood that the present disclosure may be applicable to both systematic code and non-systematic code. As mentioned above, vertical check blocks 408 are determined from cross-block bits selected from across the information CBs 410. For a given vertical check block 408, the cross-block bits may include information bits taken from different columns of different information CBs 410. For example, the cross-block bits may include input bits from column x of a first information CB 410, from column y of a second information CB 410, and from column z of a third information CB 410, where x, y and z are different. In another way of thinking, it may be considered that the cross-block bits for generating the vertical check blocks 408 may be selected by taking vertical columns of bits after the bits within an information row are optionally shuffled (also referred to as row-wise shuffling). This row-wise shuffling of the information bits may also be referred to as interleaving or row-wise interleaving.

A predefined shuffling scheme or predefined interleaver may be used to perform this shuffling. The present disclosure describes the use of interleavers for such row-wise interleaving of the information bits, for generating different vertical check blocks 408. An interleaver may be a predefined algorithm, predefined interleaving pattern or predefined transformation matrix (among other possibilities) that is applied to the row of bits to obtain a reordered row of bits. In particular, the present disclosure describes the use of a set of subblock interleavers (referred to herein as subblock interleaver set) to apply interleaving to a TB. Each subblock interleaver set includes one or more subblock interleavers, where each subblock interleaver logically splits a respective information CB 410 of the TB into a row of subblocks and performs interleaving on the respective row of subblocks. The use of subblock interleavers may be more useful than bit-based interleavers, because subblock interleavers can be defined without knowing the specific number of bits in each information CB 410.

FIG. 6 illustrates an example code structure with M information CBs 410 (namely information CB-1 410-1, information CB-2 410-2 to information CB-M 410-M, where M is a positive integer). The bits in each information CB 410 are split into a plurality of subblocks, where the k-th subblock for the i-th information CB is denoted as SBik. In this example, each information CB 410 is divided into K subblocks, where K is a positive integer, for a total of M×K subblocks in the code structure. It should be noted that the number of bits in each subblock is not necessarily equal across all subblocks (e.g., the number of bits in an information CB 410 may not be equally divisible by K). A subblock from each information CB 410 is combined together to generate a vertical code block 408 (e.g., using FEC). In particular, the k-th subblock from each information CB 410 is used to generate the k-th vertical code block. In the example shown, SB11, SB21 . . . SBM1 are combined to generate vertical check block-1 408-1; SB12, SB22 . . . SBM2 are combined to generate vertical check block-2 408-2; and so forth until SB1K, SB2K . . . SBMK are combined to generate vertical check block-M 408-M.

Having defined subblocks in this way, it should be understood that different sets of vertical check blocks 408 may be generated by shuffling (or interleaving) each row of subblocks to obtain different subblock combinations. Each set of vertical check blocks 408 may generated by applying a subblock interleaver set to obtain a respective subblock combination. It should be noted that, in order for a given set of vertical check blocks 408 to be useful for decoding the information CBs 410, it is necessary for the receiving node to know the subblock interleaver set that was used to generate the given set of vertical check blocks 408. Generally, in a retransmission scheme, different retransmissions are characterized by different RVs indices. The present disclosure describes examples for generating vertical check blocks 408 using different interleaver sets, where each subblock interleaver set is uniquely associated with a respective RV index. In this way, the receiving node is able to determine the subblock interleaver set that was used to generate vertical check blocks 408 in a given retransmission simply by knowing the RV index of that given retransmission.

The present disclosure describes techniques for defining a group of subblock interleaver sets, where each subblock interleaver set in the group can be used for generating a respective set of vertical check blocks for a number of different retransmissions. In particular, each subblock interleaver set in the group may be associated with a respective RV index. The subblock interleaver set that is associated with each respective RV index is known to both the transmitting node and the receiving node. Thus, when a retransmission is scheduled, only the RV index needs to be signaled to the receiving node. This may help to reduce the amount of information that needs to be included in the control signaling to the receiving node, thus improving efficiency and reducing the use of network resources (e.g., communication bandwidth) as well as reducing latency.

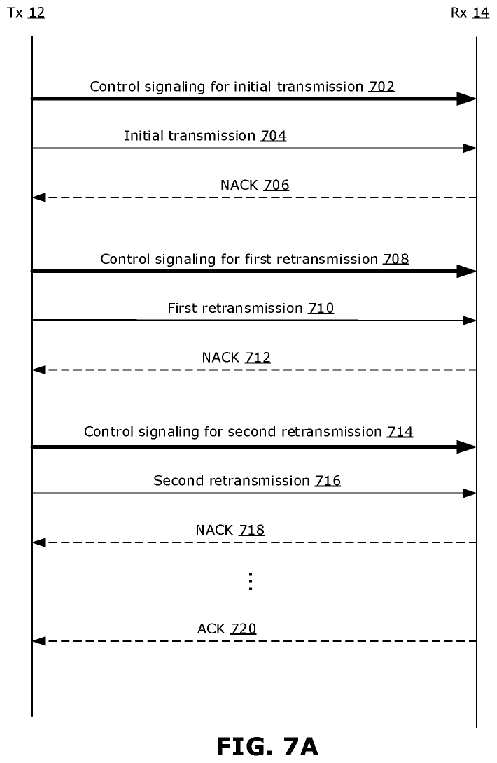

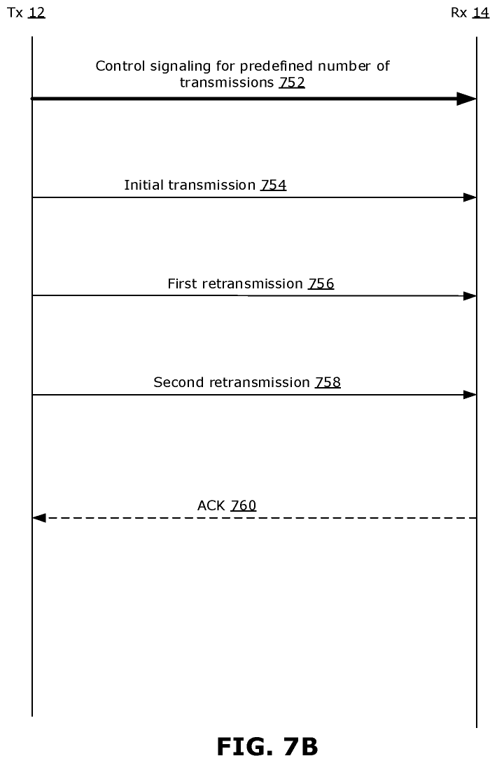

FIGS. 7A and 7B are signaling diagrams illustrating a 2D HARQ retransmission scheme, with feedback (FIG. 7A) or without feedback (FIG. 7B). It should be noted that, although FIGS. 7A and 7B (and other examples disclosed herein) are described in the context of transmission to a single receiving node (i.e., unicast), the signaling described herein (including configuration or control signaling, as well as (re)transmissions) may also be applicable to multicast, broadcast or groupcast transmissions (i.e., transmission to multiple receiving nodes). In FIGS. 7A and 7B, a transmitting node 12 (also referred to simply as a transmitter 12, denoted as Tx 12) transmits to a receiving node 14 (also referred to simply as a receiver 14, denoted as Rx 14). The transmitting node 12 may be a BS 170 (e.g., for DL transmission to an ED 110) or may be an ED 110 (e.g., for SL transmission to another ED 110, or for UL transmission to a BS 170).

FIG. 7A is described first. At 702, the transmitting node 12 may transmit a control signal (or configuration signal) to the receiving node 14 to schedule the initial transmission. The control signal may indicate the RV index to be zero (i.e., RV=0), to indicate transmitting the information block and horizontal check block, which usually corresponds to an initial transmission. The control signal may be transmitted over a control channel, which may be different from the data channel (as indicated by a thicker arrow). The type of control signal that is transmitted may depend on whether the transmitting node 12 is an ED 110 or a BS 170, for example. If the transmitting node 12 is a BS 170 and the receiving node 14 is an ED 110 (i.e., in a DL transmission), the control signal may be dynamically signaled using physical layer (or layer-1) signaling, such as downlink control information (DCI) transmissions; or may be semi-statically signaled using higher layer signaling, such as radio resource control (RRC) signaling. If the transmitting node 12 is an ED 110 and the receiving node 14 is another ED 110 (i.e., in a SL transmission), the control signal may be semi-statically signaled to the other ED 110, for example using sidelink RRC or PC5-RRC; or may be dynamically signal to the other ED 110, for example using sidelink control information (SCI) transmissions. In some examples, if the transmitting node 12 is an ED 110 and the receiving node 14 is another ED 110 (i.e., in a SL transmission) or the receiving node 14 is a BS 170 (i.e., in a UL transmission), the control signal may not be transmitted by the transmitting node 12 and may instead be transmitted from the BS 170 associated with the ED 110 that is the transmitting node 12.

The initial transmission is transmitted at 704. The initial transmission may, for example, be a transmission of the TB 402 including all of the information CBs 410 (which may include horizontal code blocks 406, in the case of systematic code), without including vertical check blocks 408. The receiving node 14 attempts to decode the received TB 402. Optionally, the receiving node 14 may transmit an indication that decoding of at least one information CB 410 failed (e.g., transmission of NACK at 706). The transmission of NACK 706 may indicate to the transmitting node 12 that a retransmission is needed. This may be referred to as a NACK-based retransmission scheme. In some examples, instead of a NACK being transmitted to indicate a failed decoding attempt, absence of an ACK may indicate to the transmitting node 12 that a retransmission is needed. This may be referred to as an ACK/NACKless retransmission scheme. Because both the NACK-based retransmission scheme and the ACK/NACKless retransmission scheme rely on presence/absence of feedback from the receiving node 14 to determine whether retransmission is required, both the NACK-based retransmission scheme and the ACK/NACKless retransmission scheme may be generally referred to as feedback-based retransmission schemes.

At 708, the transmitting node 12 may transmit another control signal (which may be similar to the control signal at 702) to the receiving node 14 to schedule the first retransmission. The control signal also includes the RV index, which may be RV=1. However, it should be understood that the first retransmission does not necessarily have to be associated with RV=1, so long as the mapping of a RV index to a specific subblock interleaver set used in the retransmission is unique; for example, the control signal may instead indicate RV=6 for the first retransmission, which may simply indicate that the subblock interleaver set associated with (e.g., mapped to) RV=6 is used to generate the VCBs for this first retransmission. The first retransmission is transmitted at 710. In particular, the first retransmission includes one or more vertical check blocks 408 from a first set of vertical check blocks 408, where the first set of vertical check blocks 408 is generated using a first subblock interleaver set associated with the RV index (e.g., RV=1) of the first retransmission. In some examples, all vertical check blocks 408 (from the first set of vertical check blocks 408) that were generated using the first subblock interleaver set may be transmitted in the first retransmission; in other examples, fewer than all vertical check blocks 408 (from the first set of vertical check blocks 408) may be transmitted in the first retransmission. The receiving node 14 attempts to decode the received TB 402 using the additional information from the first retransmission together with soft information from the previous decoding attempt. Optionally, the receiving node 14 may transmit an indication that decoding of at least one information CB 410 failed (e.g., transmission of NACK at 712); alternatively, absence of an ACK from the receiving node 14 may indicate that decoding of at least one information CB 410 failed.

At 714, the transmitting node 12 may transmit another control signal (which may be similar to the control signal at 702) to the receiving node 14 to schedule the second retransmission. Similarly to the control signal transmitted at 708, the control signal transmitted at 714 includes the RV index associated with the second retransmission, which may be RV=2 (or some other RV index that is scheduled for the second retransmission). The second transmission is transmitted at 716. Similar to the first retransmission, the second retransmission includes one or more vertical check blocks 408 from a second set of vertical check blocks 408, where the second set of vertical check blocks 408 is generated using a second subblock interleaver set associated with the RV index (e.g., RV=2) of the second retransmission. The second retransmission may include all or fewer than all of the vertical check blocks 408 (from the second set of vertical check blocks 408) that were generated using the second subblock interleaver set. The receiving node 14 attempts to decode the received TB 402 using the additional information from the second retransmission, together with soft information from the previous two decoding attempts. Optionally, the receiving node 14 may transmit an indication that decoding of at least one information CB 410 failed (e.g., transmission of NACK at 718); alternatively, absence of an ACK from the receiving node 14 may indicate that decoding of at least one information CB 410 failed.

Signaling similar to 714-718 may be repeated for each subsequent retransmission. The retransmissions may continue (with respective different sets of vertical check blocks 408 being generated using respective different subblock interleaver sets) until an indication that the TB 402 has been successfully decoded (e.g., transmission of ACK at 720) is received, or until a maximum number of retransmissions has been reached.

FIG. 7B is now described. At 752, the transmitting node 12 may transmit a control signal (or configuration signal) to the receiving node 14 to schedule a predefined number of transmissions (including an initial transmission and at least one retransmission). The control signal may indicate a sequence of RV indices corresponding to the predefined transmissions, including the RV index of the initial transmission (RV=0) and respective RV indices of each predefined retransmission. As previously noted, any RV index may be associated with any given retransmission. For example, if three retransmissions are scheduled (in addition to the initial transmission), the control signal may include the RV sequence {0, 1, 2, 3} corresponding to the initial transmission, first retransmission, second retransmission and third retransmission, respectively. However, the RV sequence may just as effectively be {0, 4, 2, 3}. The control signal may be transmitted over a control channel, which may be different from the data channel (as indicated by a thicker arrow), and may be any suitable control or configuration signaling, as previously discussed with respect to the transmission at 702.

The initial transmission is transmitted at 754. The initial transmission may, for example, be a transmission of the TB 402 including all of the information CBs 410 (which may include horizontal code blocks 406, in the case of systematic code), without including vertical check blocks 408. The receiving node 14 attempts to decode the received TB 402. In this example, the receiving node 14 does not feedback any information to the transmitting node 12 indicating whether decoding was successful or not successful.

In absence of any feedback, the transmitting node 12 performs a predefined number of retransmissions (as indicated in the control signal transmitted at 752), in this case a first retransmission at 756 and a second retransmission at 758. The first and second retransmissions each includes one or more vertical check blocks 408 from a respective first or second set of vertical check blocks 408, where the first or second set of vertical check blocks 408 is generated using a respective first or second subblock interleaver set associated with the RV index of the respective first or second retransmission. Each retransmission may include all or fewer than all of the vertical check blocks 408 that were generated using the respective first or second subblock interleaver set.

Optionally, if the receiving node 14 has successfully decoded the TB 402, an indication that the TB 402 has been successfully decoded may be transmitted (e.g., transmission of ACK at 760). Regardless of whether an ACK is received, the transmitting node 12 may stop retransmissions after the predefined number of retransmission(s) has been reached. Sending a predetermined number of retransmission(s) that is not triggered by feedback (or without receiving feedback between transmission/retransmissions) may be referred to as repetition or blind retransmission.

In some examples, a hybrid or combination of feedback-based or blind retransmission scheme may be used. For example, the transmitting node 12 may initially schedule a predefined number of transmissions (including the initial transmission and a predefined number of retransmission(s)), and the transmitting node 12 may perform the predefined number of transmissions without any feedback from the receiving node 14. After the predefined number of transmissions, the receiving node 14 may send feedback (e.g., NACK) to the transmitting node 12 if decoding of at least one information CB 410 is still unsuccessful. Thereafter, the transmitting node 12 may schedule and perform one retransmission at a time, with the receiving node 14 sending back feedback (e.g., NACK or ACK) each time, until decoding of all information CBs 410 is successfully completed. It should be understood that the present disclosure is not limited to the particular feedback mechanisms described above and shown in FIGS. 7A and 7B.

As previously mentioned, the transmitting node 12 and receiving node 14 each know the subblock interleaver set used for generating a set of vertical check blocks 408, given a particular RV index. In this way, a receiving node 14 only needs to receive the RV index from the transmitting node 12 in order to determine the subblock interleaver set that was used to generate a given set of vertical check blocks 408 in a given retransmission. The need to transmit the full subblock interleaver set to the receiving node 14 may be avoided, thus reducing consumption of network resources and/or reducing latency.

Different subblock interleaver sets may be predefined for respective different RV indices beforehand (e.g., defined in a standard, or otherwise configured between the transmitting node 12 and the receiving node 14 before the start of transmission). In some examples, a subblock interleaver set may be explicitly defined (e.g., explicitly set forth in a transformation matrix, or table) for a particular RV index. Then the appropriate subblock interleaver set may be determined, according to the explicit definition, based on the RV index associated with a retransmission.

In some examples, a subblock interleaver set may be defined using a formula or other non-explicit definition. For example, a subblock interleaver set may be defined by a seed (that is uniquely associated with a respective RV index) that may be used to compute the subblock interleaver set. In another example, a predefined formula may enable the subblock interleaver set to be computed, given the RV index (and optionally other known variables, such as the number of information CBs 410). Some example techniques for defining a subblock interleaver set, based on the RV index, will be disclosed further below.

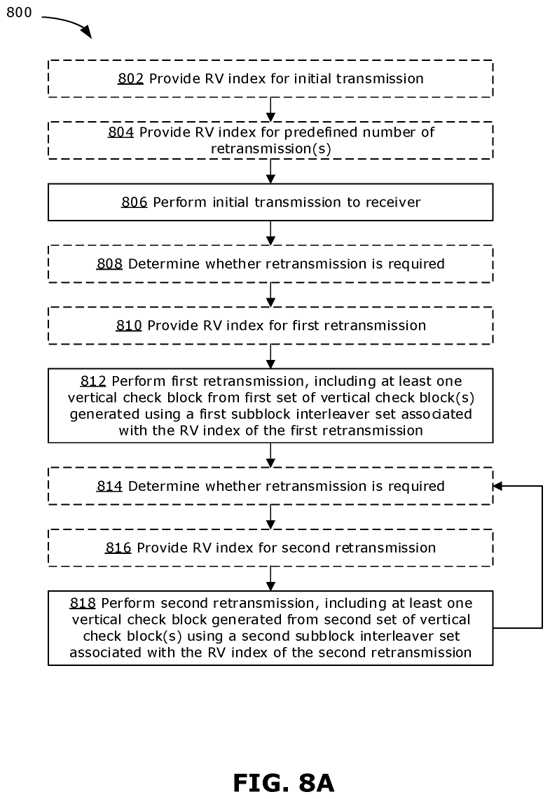

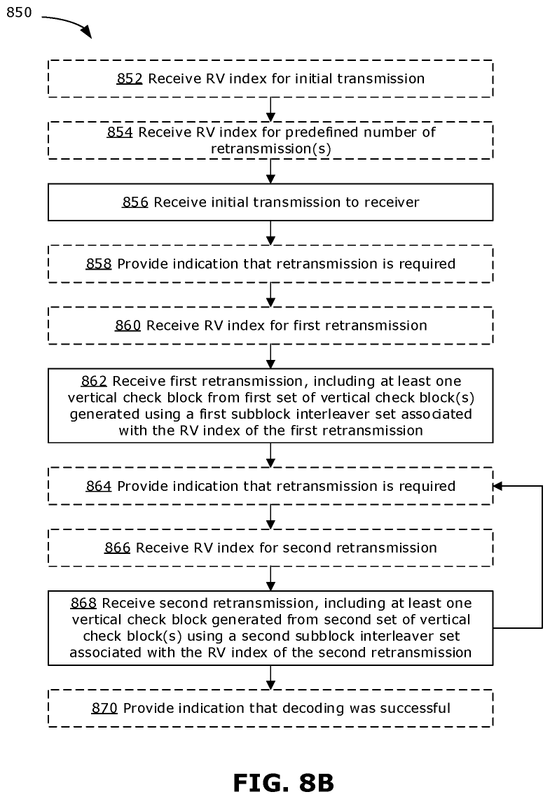

FIG. 8A is a flowchart illustrating an example method 800 that may be performed by the transmitting node 12, for example as illustrated in the signaling examples of FIGS. 7A and 7B. For example, a processing unit of the transmitting node 12 may execute instructions stored in a memory of the transmitting node 12, to cause the transmitting node 12 to perform the method 800.

Optionally, at 802, a transmitting node 12 may provide, to a receiving node 14, an RV index for an initial transmission. For example, the RV index for the initial transmission may be provided in a control signal scheduling the initial transmission. In some examples, if the transmitting node 12 is not responsible for scheduling resources (e.g., the transmitting node 12 is not a BS 170), the transmitting node 12 may receive the control signal from another node (e.g., from a BS 170), and optionally may forward the received control signal to the receiving node 14. The RV index for the initial transmission may be RV=0, for example.

Optionally, at 804, the transmitting node 12 may provide one or more RV indices for a respective predefined number of one or more retransmissions. In some examples, the one or more RV indices for the retransmission(s) may be provided together with the RV index for the initial transmission (e.g., a sequence of RV indices, including the RV index for the initial transmission and one or more RV indices for the predefined number of retransmission(s), may be included in a control signal scheduling the initial transmission and the predefined number of retransmission(s)). In some examples, step 804 may be performed when a predefined number of retransmission(s) is performed by the transmitting node 12 in the absence of feedback from the receiving node 14 (e.g., in a blind retransmission scheme). In some examples, if the transmitting node 12 is not responsible for scheduling resources (e.g., the transmitting node 12 is not a BS 170), the transmitting node 12 may receive the scheduled resources for the predefined number of retransmission(s) from another node (e.g., from a BS 170), and optionally may forward the control signal to the receiving node 14. In examples where a feedback-based retransmission scheme is used (e.g., NACK-based retransmission scheme or ACK/NACKless retransmission scheme), step 804 may be omitted.

At 806, the transmitting node 12 transmits the initial transmission to the receiving node 14. The initial transmission includes a TB having multiple information CBs. In the case where systematic code is used, the initial transmission also includes multiple horizontal check blocks corresponding to the multiple information CBs.

Optionally, at 808, the transmitting node 12 may determine whether retransmission is required. If retransmission is required, the method 800 may proceed to optional step 810. For example, the transmitting node 12 may determine that decoding of at least one information CB was not successful at the receiving node 14, based on negative feedback (e.g., in a NACK-based retransmission scheme) or absence of feedback (e.g., in an ACK/NACKless retransmission scheme) from the receiving node, and hence retransmission is required. For example, the transmitting node 12 may receive an indication (e.g., NACK) from the receiving node 14 that decoding was not successful, and hence determine that retransmission is required. In another example, the absence of an indication of success (e.g., ACK) from the receiving node 14 may indicate to the transmitting node 12 that decoding was not successful, and hence determine that retransmission is required. Optionally, if the transmitting node 12 is not responsible for scheduling resources (e.g., the transmitting node 12 is not a BS 170), the transmitting node 12 may request resources for the retransmission from another node (e.g., from a BS 170). If the transmitting node 12 is configured to transmit a predefined number of retransmission(s) (e.g., in a blind retransmission scheme), step 808 may be omitted.

Optionally, at 810, the transmitting node 12 may provide, to the receiving node 14, the RV index for a first retransmission. For example, the RV index for the first retransmission may be provided in a control signal scheduling the first retransmission. Similar to step 802, if the transmitting node 12 is not responsible for scheduling resources, the transmitting node 12 may receive the control signal from another node (e.g., from a BS 170), and optionally may forward the control signal to the receiving node 14. The RV index for the first retransmission may be RV=1, for example. In general, the RV index for the first retransmission may be any value that is assigned to the first retransmission. If the transmitting node 12 is configured to transmit a predefined number of retransmission(s) (e.g., in a blind retransmission scheme), the RV index for the first retransmission may already have been provided at step 804 and step 810 may be omitted.

At 812, the transmitting node 12 performs the first retransmission to the receiving node 14, including transmitting at least one vertical check block from a first set of vertical check block(s) that was generated using a first subblock interleaver set associated with the RV index of the first retransmission. The transmitting node 12 generates the first set of vertical check block(s) by applying the first subblock interleaver set that is defined (e.g., explicitly defined, or defined via a formula or computation) for the RV index of the first retransmission. The transmitting node 12 may include one, some or all of the vertical check block(s) from the first set of vertical check block(s) in the first retransmission. It should be noted that the first set of vertical check block(s) may be generated any time during the method 800 prior to the first retransmission. For example, the first set of vertical check block(s) may be generated prior to the initial transmission.

Optionally, at 814, the transmitting node 12 may determine whether another retransmission is required. If retransmission is required, the method 800 may proceed to optional step 816. Step 814 may be similar to step 808 described above. If the transmitting node 12 is configured to transmit a predefined number of retransmission(s) (e.g., in a blind retransmission scheme), step 814 may be omitted.

Optionally, at 816, the transmitting node 12 may provide, to the receiving node 14, the RV index for a second retransmission. If the transmitting node 12 is not responsible for scheduling resources, the transmitting node 12 may receive the control signal from another node (e.g., from a BS 170), and optionally may forward the control signal to the receiving node 14. For example, the RV index for the second retransmission may be provided in a control signal scheduling the second retransmission. The RV index for the second retransmission may be RV=2, for example. In general, the RV index for the second retransmission may be any value that is assigned to the second retransmission. If the transmitting node 12 is configured to transmit a predefined number of retransmission(s) (e.g., in a blind retransmission scheme), the RV index for the second retransmission may already have been provided at step 804 and step 816 may be omitted.

At 818, the transmitting node 12 performs the second retransmission to the receiving node 14, including transmitting at least one vertical check block from a second set of vertical check block(s) that was generated using a second subblock interleaver set associated with the RV index of the second retransmission. The transmitting node 12 generates the second set of vertical check block(s) by applying the second subblock interleaver set that is defined (e.g., explicitly defined, or defined via a formula or computation) for the RV index of the second retransmission. The transmitting node 12 may include one, some or all of the vertical check block(s) from the second set of vertical check block(s) in the second retransmission. It should be noted that the second set of vertical check block(s) may be generated any time during the method 800 prior to the second retransmission. For example, the second set of vertical check block(s) may be generated prior to the initial transmission.

The method 800 may repeat steps 814-818 (using a different RV index and a respective different subblock interleaver set for each retransmission) until an indication of success (e.g., ACK) is received from the receiving node 14 (e.g., in a feedback-based retransmission scheme) or until the predefined number of retransmission(s) has been sent (e.g., in a blind retransmission scheme).

FIG. 8B is a flowchart illustrating an example method 850 that may be performed by the receiving node 14, for example as illustrated in the signaling examples of FIGS. 7A and 7B. The method 850 may be similar to the method 800 described above, but from the viewpoint of the receiving node 14. For example, a processing unit of the receiving node 14 may execute instructions stored in a memory of the receiving node 14, to cause the receiving node 14 to perform the method 850.

Optionally, at 852, a receiving node 14 may receive an RV index for an initial transmission. For example, the RV index for the initial transmission may be received in a control signal scheduling the initial transmission. The control signal may be received from the transmitting node 12, or from some other node (e.g., a BS 170 that is not the transmitting node 12) that schedules resources for the initial transmission. The RV index for the initial transmission may be RV=0, for example.

Optionally, at 854, the receiving node 14 may receive one or more RV indices for a respective predefined number of one or more retransmissions. The RV indices may be received from the transmitting node 12, or from some other node (e.g., a BS 170 that is not the transmitting node 12) that schedules resources for the predefined number of retransmission(s). In some examples, the one or more RV indices for the retransmission(s) may be received together with the RV index for the initial transmission (e.g., a sequence of RV indices, including the RV index for the initial transmission and one or more RV indices for the predefined number of retransmission(s), may be included in a control signal scheduling the initial transmission and the predefined number of retransmission(s)). In some examples, step 854 may be performed when a predefined number of retransmission(s) is performed by the transmitting node 12 in the absence of feedback from the receiving node 14 (e.g., in a blind retransmission scheme). In examples where a feedback-based retransmission scheme is used (e.g., NACK-based retransmission scheme or ACK/NACKless retransmission scheme), step 854 may be omitted.

At 856, the receiving node 14 receives the initial transmission from the transmitting node 12. The initial transmission includes a TB having multiple information CBs. In the case where systematic code is used, the initial transmission also includes multiple horizontal check blocks corresponding to the multiple information CBs. The receiving node 14 attempts to decode the information CBs.

Optionally, at 858, the receiving node 14 may provide indication to the transmitting node 12 that retransmission is required. If retransmission is required, the method 850 may proceed to optional step 860. For example, in the case of a NACK-based retransmission scheme, if decoding of at least one information CB was not successful, the receiving node 14 may transmit negative feedback (e.g., NACK) to the transmitting node 12. In another example, in the case of an ACK/NACKless retransmission scheme, the receiving node 14 may only transmit indication of success and step 858 may be omitted even if decoding was not successful. In another example, in the case of a blind retransmission scheme, step 858 may be omitted.

Optionally, at 860, the receiving node 14 may receive the RV index for a first retransmission. The RV index may be received from the transmitting node 12, or from some other node (e.g., a BS 170 that is not the transmitting node 12) that schedules resources for the first retransmission. For example, the RV index for the first retransmission may be provided in a control signal scheduling the first retransmission. The RV index for the first retransmission may be RV=1, for example. In general, the RV index for the first retransmission may be any value that is assigned to the first retransmission. If the transmitting node 12 is configured to transmit a predefined number of retransmission(s) (e.g., in a blind retransmission scheme), the RV index for the first retransmission may already have been provided at step 854 and step 860 may be omitted.

At 862, the receiving node 14 receives the first retransmission from the transmitting node 12, including receiving at least one vertical check block from a first set of vertical check block(s) that was generated using a first subblock interleaver set associated with the RV index of the first retransmission. The first retransmission may include one, some or all of the vertical check block(s) from the first set of vertical check block(s). The receiving node 14 may attempt to decode the information CB(s), which were not successfully decoded previously, using the vertical check block(s) received in the first retransmission together with soft information from the previous decoding attempt. Notably, the receiving node 14 is able to determine the first subblock interleaver set that was used to generate the first set of vertical check block(s), based on the RV index of the first retransmission, and hence is able to make use of the vertical check block(s) without requiring the first subblock interleaver set to be transmitted to the receiving node 14.

Optionally, at 864, the receiving node 14 may provide indication to the transmitting node 12 that retransmission is required. If retransmission is required, the method 850 may proceed to optional step 866. Step 864 may be similar to step 858 described above. If the transmitting node 12 is configured to transmit a predefined number of retransmission(s) (e.g., in a blind retransmission scheme), step 864 may be omitted.

Optionally, at 866, the receiving node 14 may receive the RV index for a second retransmission. The RV index may be received from the transmitting node 12, or from some other node (e.g., a BS 170 that is not the transmitting node 12) that schedules resources for the second retransmission. For example, the RV index for the second retransmission may be provided in a control signal scheduling the second retransmission. The RV index for the second retransmission may be RV=2, for example. In general, the RV index for the second retransmission may be any value that is assigned to the second retransmission. If the transmitting node 12 is configured to transmit a predefined number of retransmission(s) (e.g., in a blind retransmission scheme), the RV index for the second retransmission may already have been provided at step 854 and step 866 may be omitted.

At 866, the receiving node 14 receives the second retransmission from the transmitting node 12, including receiving at least one vertical check block from a second set of vertical check block(s) that was generated using a second subblock interleaver set associated with the RV index of the second retransmission. The second retransmission may include one, some or all of the vertical check block(s) from the second set of vertical check block(s). The receiving node 14 may attempt to decode the information CB(s), which were not successfully decoded previously, using the vertical check block(s) received in the second retransmission together with soft information from the previous decoding attempts. Notably, the receiving node 14 is able to determine the second subblock interleaver set that was used to generate the second set of vertical check block(s), based on the RV index of the second retransmission, and hence is able to make use of the vertical check block(s) without requiring the second subblock interleaver set to be transmitted to the receiving node 14.

The method 850 may repeat steps 864-868 (with a different RV index and a respective different subblock interleaver set used for each retransmission) until all information CBs have been successfully decoded or until the predefined number of retransmission(s) has been sent (e.g., in a blind retransmission scheme).

Optionally, in a feedback-based retransmission scheme, after all information CBs have been successfully decoded, the receiving node 14 may provide an indication that decoding was successful (e.g., ACK) to the transmitting node 12.

Although unicast examples have been described, the present disclosure may also be applicable to retransmission schemes for multicast, groupcast or broadcast transmissions.

The present disclosure describes examples of subblock interleaver sets that may be used for generating different sets of vertical check blocks for respective different retransmissions. The subblock interleaver sets disclosed herein may be explicitly defined (e.g., explicitly defined using respective transformation matrices, or defined in tables) and explicitly associated with respective RV indices (e.g., defined by a standard). The subblock interleaver sets disclosed herein may also be implicitly defined for respective RV indices, for example according to a formula or other deterministic relationship.

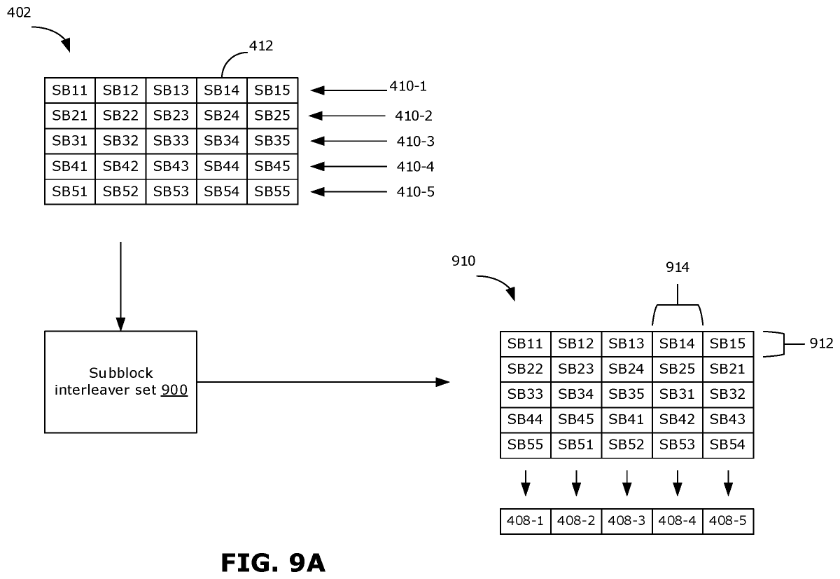

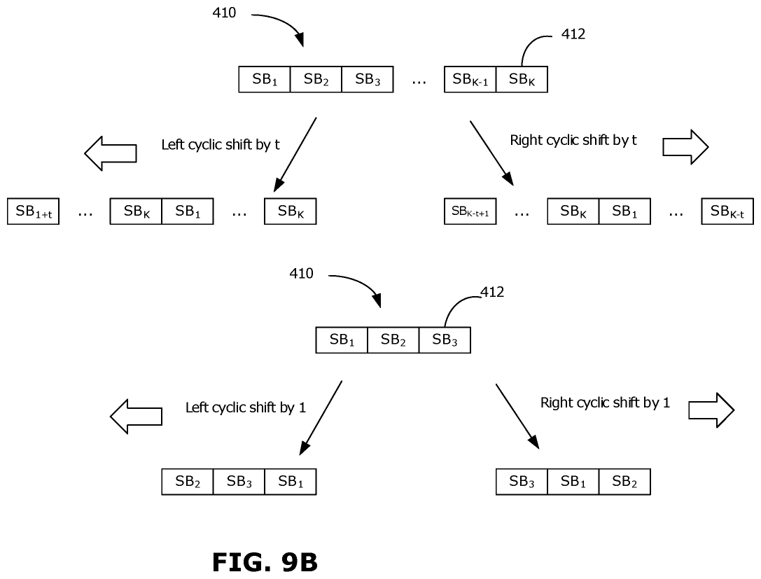

To assist in understanding the following discussion, some terminology is first introduced. FIG. 9A is a diagram of an example transport block 402 that has five information CBs 410-1 to 410-5 (generally referred to as information CB 410). Each information CB 410 may correspond to a row of the TB 402. The bits of each information CBs 410 may be logically divided into a row of subblocks 412, as mentioned previously. In this example, each information CB 410 is split into a row of five subblocks 412, where the k-th subblock 412 of the i-th information CB 410 is denoted SBik.

In the initial transmission (e.g., having RV index RV=0), the subblocks 412 are in their natural order. By natural order, it is meant that the subblocks 412 are arranged such that the order of the bits in each information CB 410 is unshuffled. It should be understood that, although the TB 402 is illustrated as being divided into subblocks 412 prior to any subblock interleaving being applied, this is only for ease of understanding. In practical applications, the logical splitting of the TB 402 into subblocks 412 may be performed only when subblock interleaving is applied, and not in the initial transmission of the TB 402. FIG. 9A illustrates the TB 402 omitting horizontal check blocks 406, for simplicity. However, it should be understood that the initial transmission may include horizontal check blocks 406.

In a given retransmission having a given RV index, a subblock interleaver set 900 associated with the given RV index is applied to obtain a subblock combination 910. The subblock interleaver set 900 may be realized using software (e.g., using a transformation matrix to compute the subblock combination 910), hardware (e.g., using a shift register to apply cyclic shifting), or a combination of software and hardware. The subblock combination has subblocks 412 arranged by rows 912 and columns 914. In the example of FIG. 9A, after applying the subblock interleaver set 900 the subblocks 412 have been interleaved (also referred to as shuffled) within each row 912, which may be referred to as row-wise interleaving. It may be noted that the subblocks 412 in the first row (corresponding to information CB 410-1) are not interleaved. The first row may be left in the natural order to serve as a reference row, which provides a reference for undoing the interleaving (e.g., at the receiving node); however, any row may be used as the reference row. In some examples a reference row may not be needed. It may also be noted that there is no column-wise interleaving of subblocks 412 (i.e., each subblock interleaver in the subblock interleaver set 900 applies subblock interleaving to a respective row of subblocks 412).

A set of vertical check blocks 408-1 to 408-5 (generally referred to as vertical check blocks 408) is generated from the subblock combination 910. In particular, the bits from each column 914 of subblocks are the information bits used to generate a respective one vertical check block 408.

In general, in order to maximize or increase the amount of useful information carried in each retransmission, the set of vertical check blocks 408 that is used for each retransmission should be generated from a respective subblock combination 910 whose columns 914 of subblocks have preferably no overlap with the columns 914 of any other subblock combination 910 used for any other retransmission. By no overlap, it is meant that there is no column 914 of subblock that is repeated among different subblock combinations 910, and that there is no pair of subblocks 412 that is found together in a column more than once among the different subblock combinations 910. Because the vertical check blocks 408 are generated from columns 914 of subblocks, having no overlap of columns 914 across different subblock combinations 910 means that every vertical check block 408 is generated from a different combination of subblocks 412 (i.e., a different combination of information bits across the information CBs 410). Thus, every vertical check block 408 provides different information to assist in decoding. In this way, the performance of the overall wireless system is improved, because there is less repetition of coded bits in the retransmissions. Some performance gain can be achieved even if there is some overlap of columns 914 (e.g., there is one or a few pairs of subblocks 412 that are found together in a column in more than one subblock combination 910).

The present disclosure describes examples that may be used to define subblock interleaver sets, such that the subblock combinations resulting from the interleaving have with little or no overlap of columns. In particular, the present disclosure describes examples in which subblock interleaver sets can be defined based on the RV index.

As previously explained, different subblock interleaver sets 900 are used for different RV indices. In the following discussion, different techniques for defining a group of subblock interleaver sets 900 are described.

An example technique for defining a group of subblock interleaver sets is now described. In this example technique, which may be referred to as prime number-based cyclic shifting, a group of subblock interleaver sets has K unique subblock interleaver sets, which can be used to generate respective K sets of vertical check blocks for K different RV indices (where K is a positive integer). In particular, in this example technique K is a prime number. Each subblock interleaver set in the group of subblock interleaver sets is associated with a respective RV index from 1 to K or in general, associated with a respective K different RV index (i.e., not necessarily from 1 to K). For example, the subblock interleaver set associated with RV index RV=1 may be used as the first subblock interleaver set for generating the first set of vertical check blocks for a first retransmission, the subblock interleaver set associated with RV index RV=2 may be used as the second subblock interleaver set for generating the second set of vertical check blocks for a second retransmission, and so forth until the K-th subblock interleaver set associated with RV index RV=K. However, it should be understood that the numerical value of RV indices (and hence the order of the subblock interleaver sets) may not necessarily match the order of retransmission (e.g., the first retransmission may have RV index other than RV=1).

For a TB 402 having M information CBs 410 (where M is a positive integer), the value of K is defined as the minimum prime number such that K is greater than or equal to M. Each subblock interleaver set in the group of K subblock interleaver sets splits the bits of each information CB 410 into K subblocks 412, such that the TB 402 is divided into M×K subblocks 412 (i.e., M information CBs 410 each divided into K subblocks 412). It should be noted that the number of bits in each subblock 412 is not necessarily exactly equal, but may be substantially equal (e.g., number of bits in different subblocks 412 may differ by no more than a few bits).

Then, the subblock interleaver set associated with RV index RV=j (where j is an integer value between 1 and K, inclusive), when applied to the TB 402, results in a subblock combination where each row of subblocks is shifted as follows. For the i-th row of subblocks (i.e., corresponding to the i-th information CB 410), the subblock interleaver set applies a cyclic shift that shifts the subblocks in that i-th row by an amount equal to (j−1)*(i−1)mod K, where mod K denotes the operation modulus K. It should be noted that the cyclic shift may be a left cyclic shift or a right cyclic shift, provided that the same shift direction (i.e., left or right shift) is used for all K subblock interleaver sets.

Applying a cyclic shift by an amount equal to (j−1)*(i−1)mod K may be more generally described as applying an amount of cyclic shift that is a function of (j+c₁)*(i+c₂), where j is the RV index associated with the subblock interleaver set, i is the row number (i.e., the index of the information CB), and c₁ and c₂ are each integer constants. The constants c₁ and c₂ mean that the values of j and i may start from any value (not necessarily starting at 0 or starting at 1).

FIG. 9B illustrates examples that help in understanding left and right cyclic shifting. Consider an information CB 410 (which may be a row of a TB 402) that has a row of K subblocks 412 in the order of (SB₁, SB₂, . . . , SB_{K}), where the subscript 1, 2, . . . , K is the index of the subblocks (denoted as SB). If a subblock interleaver applies a left cyclic shift with an amount equal to t (where t is an integer and 0<=t<=K−1), which is equivalent to a cyclic shift of each subblock to the left by t positions, this will result in K subblocks 412 in the order of (SB₍₁₊ₜ₎, . . . , SB_{K}, SB₁, . . . , SBₜ). Similarly, if a subblock interleaver applies a right cyclic shift with an amount equal to t (where t is an integer and 0<=t<=K−1), which is equivalent to a cyclic shift of each subblock to the right by t positions, this will result in K subblocks in the order of (SB_{(K-t+1)}, . . . , SB_{K}, SB₁, . . . , SB_{(K-t)}). As an example, FIG. 9B also illustrates an information CB 410 having three subblocks 412 (i.e., K=3), the original order (or natural order) of K subblocks is (SB₁, SB₂, SB₃), a left cyclic shift with cyclic shift amount t=1 will result in subblocks in the order of (SB₂, SB₃, SB₁), and a right cyclic shift with cyclic shift amount t=1 will result in subblocks in the order of (SB₃, SB₁, SB₂).

By defining a group of K subblock interleaver sets in this way, K sets of vertical check blocks can be generated for retransmissions using K different RVs (corresponding to RV indices 1 to K), where RV index RV=0 is reserved for transmitting the information blocks and horizontal check blocks, which usually corresponds to the initial transmission. The RV indices 1 to K may be used in any order for performing the retransmissions. If fewer than K RV index are defined, then a subset of the K subblock interleaver sets may be used.

In the group of K subblock interleaver sets defined according to the above example, it can be guaranteed that there is no repetition of any column of subblocks across the subblock combinations obtained using the group of K subblock interleaver sets. Further, there is no repetition of any pair of subblocks used for one vertical check block across the subblock combinations obtained using the group of K subblock interleaver sets (i.e., the same two subblocks are not found in the same column more than once across all of the subblock combinations in the group of K subblock interleaver sets). The result is that every vertical check block 408 generated for all K RV indices is generated from a unique, non-overlapping combination of subblocks across the information CBs 410. This property, which may be referred to herein as the subblock combinations having “non-overlapping columns”, may help to maximize usefulness of the information carried in each retransmission, thus maximizing performance of the overall wireless system.

Some example implementations of the above-defined group of K subblock interleaver sets are now described.

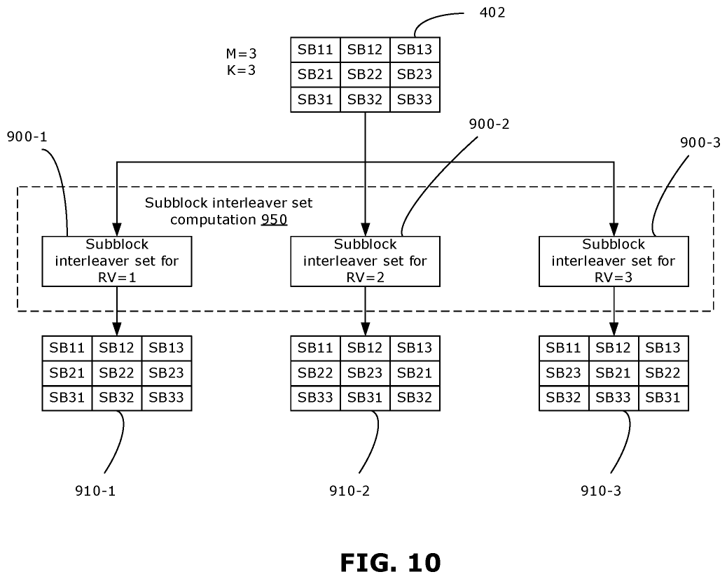

FIG. 10 illustrates an example implementation in the case where the TB 402 contains three information CBs 410. The number of information CBS 410 is denoted as M=3. Since K is defined as the smallest prime number greater than or equal to the number of information CBs 410, in this example K=3. Thus, FIG. 10 illustrates an implementation of the above definition of subblock interleavers set, where three different subblock interleaver sets are defined for RV indices 1 to 3.

As shown in FIG. 10, the subblock interleaver sets 900-1, 900-2 and 900-3 (for RV=1, RV=2 and RV=3, respectively) may be computed by an optional subblock interleaver set computation module 950. For example, the subblock interleaver set computation module 950 may be a module implemented at the transmitting node 12 (e.g., implemented using software, hardware, or a combination thereof) that computes the cyclic shift for each row of subblocks, depending on the RV index, as described above. The subblock interleaver set computation module 950 may be used by the transmitting node 12 to define the appropriate subblock interleaver set 900-1, 900-2, 900-3, depending on the RV index of the retransmission, at the time that a set of vertical check blocks needs to be generated. Alternatively, the subblock interleaver sets 900-1, 900-2, 900-3 may be defined ahead of time (e.g., predefined in a standard, or defined using the subblock interleaver set computation module 950) for the values M=3, K=3, any time prior to performing the retransmissions. Similarly, at the receiving node 14, the subblock interleaver sets 900-1, 900-2, 900-3 may be predefined or may be computed by the receiving node 14 as needed when retransmissions are received.

For ease of reference, the subblock interleaver sets 900-1, 900-2 and 900-3 (associated with RV=1, RV=2 and RV=3, respectively) may be referred to as first, second and third subblock interleaver sets, respectively, however it should be understood that the use of the terms “first”, “second” and “third” is not intended to limit the order in which the subblock interleaver sets 900-1, 900-2, 900-3 are used in retransmissions. The first subblock interleaver set 900-1, when applied to the TB 402, results in a first subblock combination 910-1; the second subblock interleaver set 900-2, when applied to the TB 402, results in a second subblock combination 910-2; and the third subblock interleaver set 900-3, when applied to the TB 402, results in a third subblock combination 910-3. It may be noted that the first subblock combination 910-1 has the subblocks in their natural order.

As shown in FIG. 10, the subblock interleaver sets 900-1, 900-2 and 900-3 each interleave the subblocks by applying cyclic shift to each row as follows:

| | j = 1 | j = 2 | j = 3 |
|---|---|---|---|
| i = 1 | 0 | 0 | 0 |
| i = 2 | 0 | 1 | 2 |
| i = 3 | 0 | 2 | 1 |

where j denotes the RV index (i.e., RV = 1, RV = 2 and RV = 3) for the respective subblock interleaver sets 900-1, 900-2 and 900-3, and i denotes the row of subblocks.

As shown in the above table, the cyclic shift that is applied to each row can be computed according to (j−1)*(i−1)mod K (in the above example, K=3). For example, for the first subblock interleaver set 900-1, j=1 (i.e., RV=1) hence there is no cyclic shift applied to any of the rows.

For the second subblock interleaver set 900-2, j=2 (i.e., RV=2) hence the cyclic shift applied to the first row is (1)*(0)mod 3=0; the cyclic shift applied to the second row is (1)*(1)mod 3=1; and the cyclic shift applied to the third row is (1)*(2)mod 3=2. The cyclic shift applied by the third subblock interleaver set 900-3 may be determined similarly. Notably, no pair of any two subblocks appears together more than once in any column across all three subblock combinations 910-1, 910-2, 910-3, thus the subblock combinations 910-1, 910-2, 910-3 have non-overlapping columns.

In the example of FIG. 10, the number of information CBs 410 (denoted as M) is a prime number. Hence, the number of subblocks per information CB 410 (denoted as K) is the same as the number of information CBs 410 (i.e., K=M).

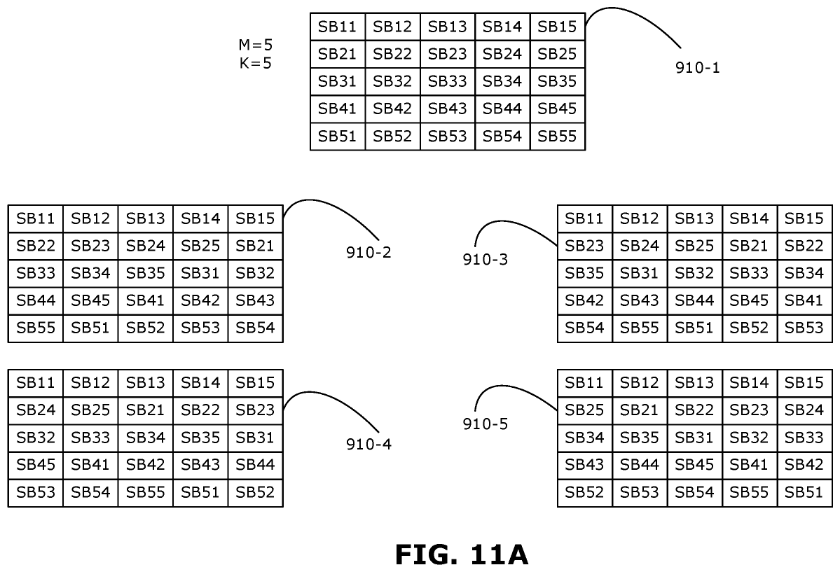

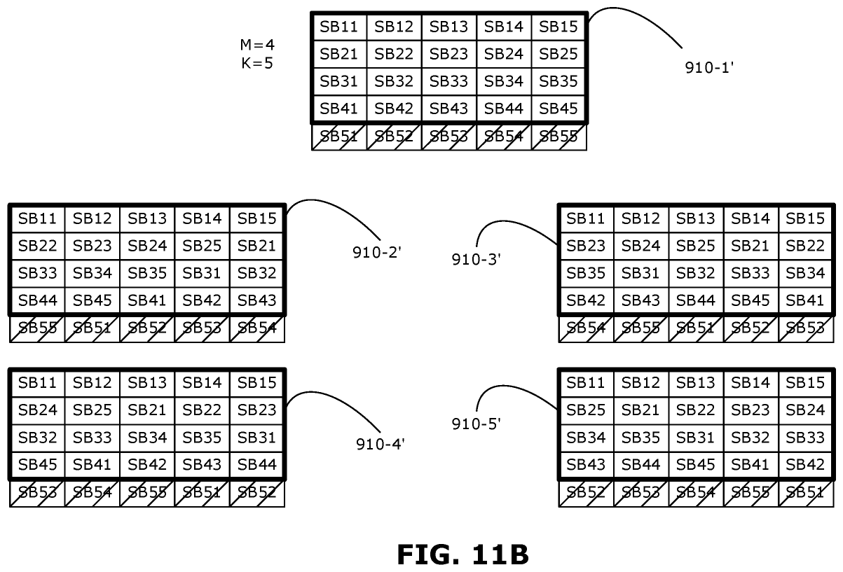

FIG. 11A illustrates an example in which the number of information CBs 410 is five (M=5). Hence, the number of subblocks per information CB 410 is also five (K=5). Using the prime number-based cyclic shifting of subblocks, as described above, five subblock combinations 910-1 to 910-5 may be obtained as shown.

The cyclic shift in each row of the subblock combinations 910-1 to 910-5 in the example of FIG. 11A are as follows:

| | j = 1 | j = 2 | j = 3 | j = 4 | j = 5 |
|---|---|---|---|---|---|
| i = 1 | 0 | 0 | 0 | 0 | 0 |
| i = 2 | 0 | 1 | 2 | 3 | 4 |
| i = 3 | 0 | 2 | 4 | 1 | 3 |
| i = 4 | 0 | 3 | 1 | 4 | 2 |
| i = 5 | 0 | 4 | 3 | 2 | 1 |

where j denotes the RV index (i.e., RV = 1, RV = 2, RV = 3, RV = 4 and RV = 5), and I denotes the row of subblocks.

Again, it may be noted that, no combination of any two (or more) subblocks) appears more than once in any column across all five subblock combinations 910-1 to 910-5, thus the subblock combinations 910-1 to 910-5 all have non-overlapping columns.

In the case where the number of information CBs 410 is not a prime number then K is defined as the smallest prime number that is greater than M. A group of K subblock interleaver sets can then be defined, as discussed above. In particular, the group of K subblock interleaver sets may be defined assuming there are K rows of subblocks (where K>M) to be interleaved. If there are fewer than K rows of subblocks (i.e., the number of information CBs 410 is fewer than K), then any M subblock interleavers (for interleaving any M rows) within the subblock interleaver set may be used. That is, if the subblock interleaver set defines subblock interleaving patterns for K rows of subblocks and there are fewer than K information CBs 410 in the TB 402, then a subset of the K subblock interleavers in the subblock interleaver set may be selected and used for interleaving the information CBs 410.

FIG. 11B illustrates an example in which the number of information CBs 410 is four (i.e., M=4). Hence, the number of subblocks per information CB 410 is five (i.e., K=5) (since five is the smallest prime number that is greater than four). The subblock combinations defined for K=5, as shown in FIG. 11A, may be applied to the four information CBs 410 by selecting the subblock interleavers defined for any four rows.

In a simple example, the first four subblock interleavers in each subblock interleaver set may be selected, to obtain modified subblock interleaver sets 910-1′ to 910-5′. The remaining fifth subblock interleaver (which is defined for the fifth row of subblocks) may be ignored or discarded. This is illustrated in FIG. 11B by a thicker border around the four subblock interleavers selected for each modified subblock interleaver set 910-1′ to 910-5′, and shading out of the subblock interleaver that is not used. The information bits from the subblocks of the first four information CBs in each column are used to generate the respective vertical check blocks.

Different groups of subblock interleaver sets may be predefined for different expected (or common) values of K ahead of time and stored in memory (so that they do need to be computed each time they are needed). For example, the cyclic shifting of each row of subblocks may be computed ahead of time and stored (e.g., as a look-up table indicating the amount of cyclic shift per row) for expected values of K. Alternatively or additionally, a group of subblock interleaver sets, defined using cyclic shifting in the manner described above, may be predefined in a standard (e.g., as tables indicating the amount of cyclic shift per row). Alternatively or additionally, the resultant subblock combination that corresponds to a specific RV index after performing the cyclic shift operation above may be predefined in the standard (e.g., as tables indicating the resultant subblock combination).

In general, the above-described prime number-based cyclic shifting technique defines a group of subblock interleaver sets. For each given subblock interleaver set in the group, the subblock interleavers in the given subblock interleaver applies a certain amount of cyclic shifting to each respective row of subblocks, different amounts of cyclic shifting being applied to different rows of subblocks (except for the special case of RV=1, where there is zero cyclic shift applied to all rows of subblocks)). The difference in the amount of cyclic shift applied to any two given rows of subblocks by a given subblock interleaver set is not duplicated in the same two rows by any other subblock interleaver set in the defined group of subblock interleaver sets. This property holds, provided the number of subblocks per information CB is a prime number that is equal to or greater than the number of information CBs. The group of subblock interleaver sets defined using the prime number-based cyclic shifting technique disclosed above will always result in subblock combinations having non-overlapping columns. This can be mathematically proven, as discussed below.

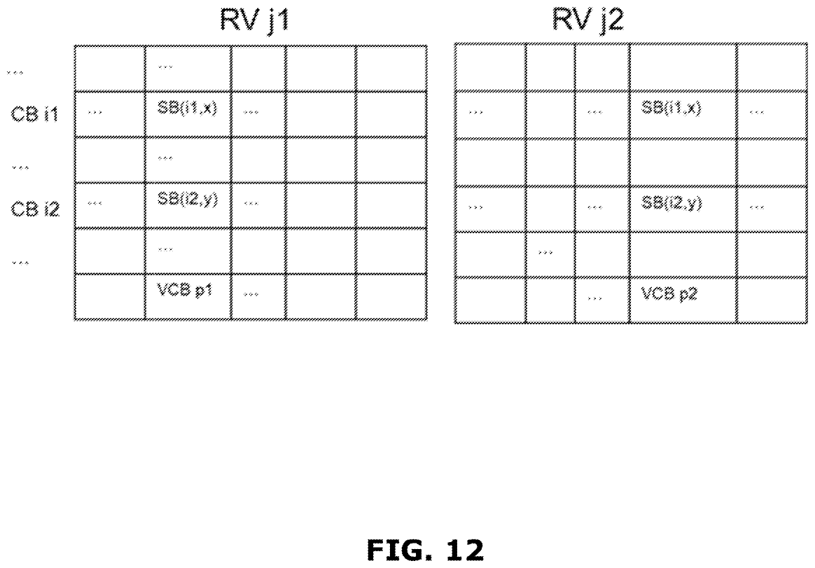

Consider FIG. 12, which illustrates the scenario where a pair of subblocks occurs together in a column more than once. In particular, two subblocks are identified. Subblock SB(i₁,x) is the x-th subblock belonging to the information CB denoted CBᵢ₁; and subblock SB(i₂, y) is the y-th subblock belonging to the information CB denoted CBᵢ₂.

Assuming the pair of subblocks SB(i₁,x) and SB(i₂,y) is found together in a column more than once (i.e., there are at least two columns that overlap because they contain the same pair of subblocks), then there must be two vertical check blocks (denoted VCBₚ₁ and VCBₚ₂) belonging to respective two RV indices (denoted as RVⱼ₁ and RVⱼ₂) that share the same pair of subblocks SB(i₁,x) and SB(i₂,y).

According to the above-disclosed technique for defining subblock interleaver sets, each row of subblocks is generated based on a cyclic shift of the corresponding row relative to its natural order (i.e., its order in the initial transmission RV=0). Thus, the difference between the column location of subblock SB(i₁,x) in RVⱼ₁ and in RVⱼ₂ is the relative cyclic shift of row i₁ in RVⱼ₁ with respect to row i₁ in RVⱼ₂, which is also equal to p₂−p₁. Same conclusion applies to subblock SB(i₂, y).

Thus, using the computation of row-wise cyclic shift disclosed above:

$$\begin{matrix}{p}_{2} - {p}_{1} = cyclic shift of row {i}_{1} in {RV}_{j 1} with \\ respect to row {i}_{1} in {RV}_{j 2} \\ = ( ( {j}_{1} - 1 ) * ( {i}_{1} - 1 ) - ( {j}_{2} - 1 ) * ( {i}_{1} - 1 ) ) mod K \\ = ( {j}_{1} - {j}_{2} ) * ( {i}_{1} - 1 ) mod K\end{matrix} \qquad ( 1 )$$

The same computation can be performed with respect to the cyclic shift of row i₂:

$${p}_{2} - {p}_{1} = ( {j}_{1} - {j}_{2} ) * ( {i}_{2} - 1 ) mod K \qquad ( 2 )$$

The only way both (1) and (2) can be true is if:

$$( {j}_{2} - {j}_{1} ) * ( {i}_{2} - {i}_{1} ) mod K = 0$$

However, K is defined as a nonzero prime number, j₁≠j₂ and i₁≠i₂:

$$1 \leq {j}_{1} \neq {j}_{2} \leq K , and 1 \leq {i}_{1} \neq {i}_{2} \leq K$$

Thus, (1) and (2) cannot both be true, therefore the assumption that the pair of subblocks SB(i₁,x) and SB(i₂,y) is found together in more than one column must be false. In other words, this proves that there is no pair of subblocks that occurs together in a column more than once (i.e., no overlapping columns) across all K RVs.

Although the efficiency and performance of the overall wireless communication system may be improved when the subblock combinations all have non-overlapping columns across all K RVs (thus maximizing the amount of useful information contained in each retransmission), a retransmission scheme that uses vertical check blocks is still an improvement over other conventional retransmission schemes (e.g., CBG-based retransmission schemes) even if there is some overlapping of columns in the subblock combinations used for generating the vertical check blocks. Accordingly, the present disclosure describes some other example subblock interleaver sets that may be used to generate vertical check blocks.

Another example technique for defining a group of subblock interleaver sets is now described. In this example, in addition to applying a row-wise cyclic shift to each row of subblocks, each subblock interleaver set also applies a vertical cyclic shift, which shifts the amount of cyclic shift applied to each row after the first row in the vertical direction (up or down). It should be noted that the vertical cyclic shift may be applied in an up or down direction, provided that the same shift direction is used for all applicable subblock interleaver sets. This technique may be referred to as dual subblock-based cyclic shifting.

With the dual subblock based cyclic shift method, the RV with index 0 may similarly correspond to transmitting the original information blocks and horizontal code blocks, which is typically used for initial transmission. Then, the subblock interleaver set associated with RV index j=1 is the same as the previously described cyclic shift method, where the cyclic shift amount is 0 for all rows. For 1<j≤K, for the i-th row of subblocks (i.e., corresponding to the i-th information CB 410), the subblock interleaver set applies a cyclic shift that shifts the subblocks in that i-th row by an amount equal to (i−j)mod(K−1)+1, where mod (K−1) denotes the operation modulus (K−1);

This dual subblock-based cyclic shifting may be used for defining a group of subblock interleaver sets to generate a prime number of vertical check blocks (over a prime number of RVs), or for any number of vertical check blocks (not necessarily limited to prime numbers). In this example technique, the number of subblocks per information CB 410 is set to be equal to the number of information CBs 410 (i.e., M=K).

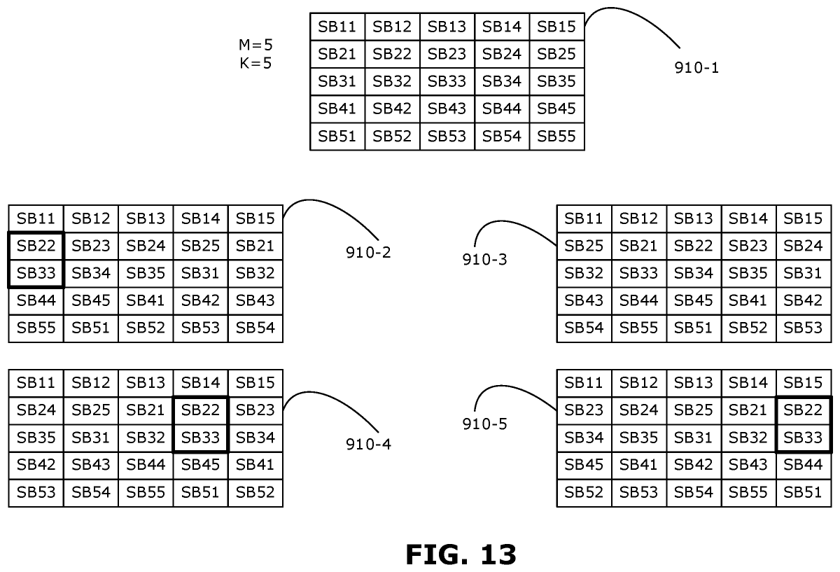

FIG. 13 illustrates an example using the dual subblock-based cyclic shifting technique to define the group of subblock interleaver sets, in which the number of information CBs 410 is five (M=5). Hence, the number of subblocks per information CB 410 is also five (K=5). Using dual subblock-based cyclic shifting of subblocks, five subblock combinations 910-1 to 910-5 may be obtained as shown.

The cyclic shift in each row of the subblock combinations 910-1 to 910-5 in the example of FIG. 13 are as follows:

| | j = 1 | j = 2 | j = 3 | j = 4 | j = 5 |
|---|---|---|---|---|---|
| i = 1 | 0 | 0 | 0 | 0 | 0 |
| i = 2 | 0 | 1 | 4 | 3 | 2 |
| i = 3 | 0 | 2 | 1 | 4 | 3 |
| i = 4 | 0 | 3 | 2 | 1 | 4 |
| i = 5 | 0 | 4 | 3 | 2 | 1 |

where j denotes the RV index (i.e., RV = 1, RV = 2, RV = 3, RV = 4 and RV = 5), and I denotes the row of subblocks.

It can be seen that for RV index j=3, the row-wise cyclic shift amount in rows i=2 to 5 is the same as vertically cyclic shifting the row-wise cyclic shift amount for the corresponding rows in RV index j=2 by one in the down direction. For example, the row-wise cyclic shift amount found in row i=2 in RV index j=2 has been vertically cyclic shifted down by one and is found in row i=3 in RV index j=3; similarly the row-wise cyclic shift amount found in row i=5 in RV index j=2 has been vertically cyclic shifted down by one and is found in row i=2 in RV index j=3 (note that no row-wise cyclic shifting is applied to row i=1 for any of the RVs, such that row i=1 may be used as a reference row). This vertical cyclic shifting of the row-wise cyclic shift amounts is continued for RV j=4 and RV j=5. Thus, the row-wise cyclic shift amounts for RV j=4 are obtained by vertically cyclic shifting the row-wise cyclic shift amounts for corresponding rows in RV index j=3 by one, and so forth. It may be seen that the vertical cyclic shifting of row-wise cyclic shift amounts described above may be computed for row i (i>1) and column j (j>1) using the formula (i−j)mod(K−1)+1 (where K=5 in this example).

The dual subblock-based cyclic shifting described above guarantees that no two rows share the same cyclic shift value in any retransmission. However, unlike the prime number-based cyclic shifting previously discussed, the dual subblock-based cyclic shifting does not guarantee that the relative amount of cyclic shift between any two rows is not repeated. For example, as seen in the above table, the relative amount of cyclic shift between rows i=2 and i=3 is repeated in j=2, j=4 and j=5. As shown in FIG. 13, the result is that there is more than one column that has the same subblock pair between the second and third row. For example, the subblock pair SB22 and SB33 is found together in a column in the second, fourth and fifth subblock combinations 910-2, 910-4 and 910-5 (as indicated by dark outlines). Despite this repetition of subblock pairs, the amount of repetition is relatively small, and the dual subblock-based cyclic shifting technique for defining a group of subblock interleaver sets may still be useful for generating vertical check blocks over different RVs. It should also be noted that the dual subblock-based cyclic shifting method may be used regardless of whether K is a prime number or not.

Another example technique for defining a group of subblock interleaver sets is now described. This example technique, which may be referred to herein as prime factor-based cyclic shifting, may be used where the number of information CBs 410 is not a prime number (i.e., M is not a prime number) and it is desired for the number of subblocks per information CB 410 to be equal to the number of information CBs 410 (i.e., M=K). It may be noted that K defines the number of subblocks per information CB 410, and K also defines the number of vertical check blocks that can be generated using a subblock interleaver set.

In prime factor-based cyclic shifting, a value K1 is defined where K1 is the smallest prime number that is a factor of K (where K is equal to the number of information CBs 410), and a value L is defined where L is the smallest positive integer such that the value K−L is a prime number.

Then, the subblock interleaver set associated with RV index RV=j (where j is an integer between 1 and K−L, inclusive), when applied to the TB 402, results in a subblock combination where each row of subblocks is shifted as follows. For the i-th row of subblocks (where i is an integer between 1 and K, inclusive), the subblock interleaver set applies a cyclic shift that shifts the subblocks in that i-th row by an amount equal to (j−1)*(i−1)mod(K−L) if the conditions (i) (K1+1≤j≤K−L) and (ii) (1≤i≤K−L) are satisfied. If the conditions (i) and (ii) are not satisfied, then the subblock interleaver set applies a cyclic shift that shifts the subblocks in the i-th row by an amount equal to (j−1)*(i−1)mod K.

More generally, a group of subblock interleaver sets may be defined, where one (or more) subblock interleaver set in the group is defined to apply an amount of cyclic shift to each row of subblocks, where the amount of cyclic shift is a function of (j+c₁)*(i+c₂)mod(K−L) for at least a subset of the information CB rows (e.g. for the first K−L rows), where j is the RV index associated with the subblock interleaver set, i is the row number (i.e., the index of the information CB), c₁ and c₂ are each integer constants, and K−L is a prime number.

Defining the group of subblock interleaver sets using the prime factor-based cyclic shifting technique described above results in the first K1 subblock interleaver sets being defined similar to the prime number-based cyclic shifting technique described previously. Accordingly, the subblock combinations resulting from the first K1 subblock interleaver sets can be guaranteed to have no overlapping columns. Further subblock interleaver sets are defined (from the (K1+1)-th subblock interleaver set to the (K−L)-th subblock interleaver set) that do not necessarily have this property, but that should have a relatively small number of repeated subblock pairs in the columns. This is because K−L is a prime number and close to K, and the first K−L row for the (K1+1)-th subblock interleaver set to the (K−L)-th subblock interleaver set has a similar property to the prime number-based cyclic shift design. It should be noted that the number of subblock interleaver sets that is defined using the prime factor-based cyclic shifting technique may be fewer than K.

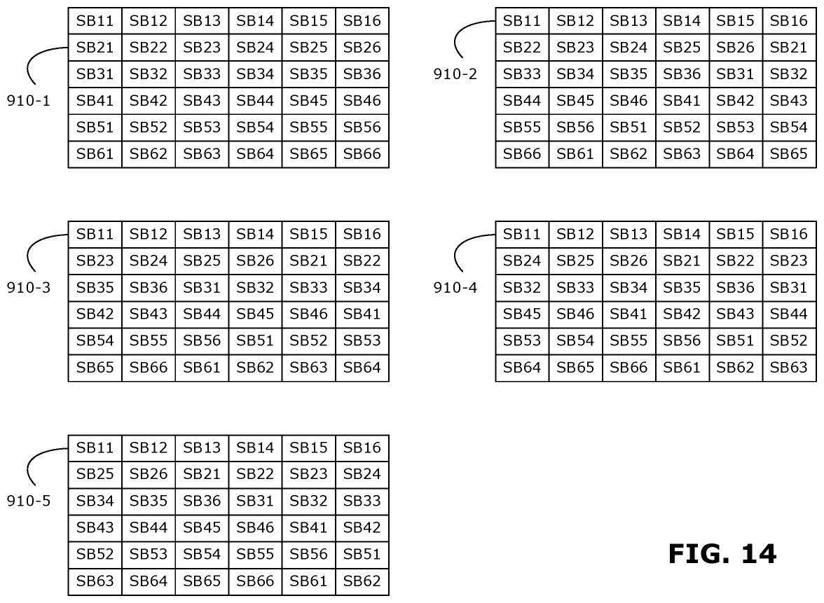

FIG. 14 illustrates an example using the prime factor-based cyclic shifting technique to define the group of subblock interleaver sets, in which the number of information CBs 410 is six (M=6). Hence, the number of subblocks per information CB 410 is also six (K=6). the smallest prime number that is a factor of K is two, hence K1=2. The smaller positive integer L such that K−L is a prime number is L=1 (thus K−L=6−1=5). Thus, using the prime factor-based cyclic shifting technique, the first two subblock combinations 910-1 and 910-2 may be obtained by applying cyclic shift to each row according to the computation (j−1)*(i−1)mod 6. Then the third to fifth subblock combinations 910-3 to 910-5 may be obtained by applying cyclic shift to each row according to the computation (j−1)*(i−1)mod 5; with the exception of row 6 and columns 1 and 2, which is cyclic shifted by the amount (j−1)*(i−1)mod 6.

Specifically, the cyclic shift in each row of the subblock combinations 910-1 to 910-5 in the example of FIG. 14 are as follows:

| | j = 1 | j = 2 | j = 3 | j = 4 | j = 5 |
|---|---|---|---|---|---|
| i = 1 | 0 | 0 | 0 | 0 | 0 |
| i = 2 | 0 | 1 | 2 | 3 | 4 |
| i = 3 | 0 | 2 | 4 | 1 | 3 |
| i = 4 | 0 | 3 | 1 | 4 | 2 |
| i = 5 | 0 | 4 | 3 | 2 | 1 |
| i = 6 | 0 | 5 | 4 | 3 | 2 |

where j denotes the RV index (i.e., RV = 1, RV = 2, RV = 3, RV = 4 and RV = 5), and I denotes the row of subblocks.

It can be seen that the first two subblock combinations 910-1 and 910-2 have non-overlapping columns, but the third to fifth subblock combinations 910-3 to 910-5 have some column overlap. However, the third to fifth subblock combinations do not have column overlap if only row 1 to row 5 are included, therefore the amount of column overlap is relatively small.

Another example technique for defining a group of subblock interleaver sets is now described. This example technique, which may be referred to herein as RV index skipping, may be used where the number of information CBs 410 is not a prime number (i.e., M is not a prime number) and it is desired for the number of subblocks per information CB 410 to be equal to the number of information CBs 410 (i.e., M=K).

In RV index skipping, the subblock interleaver set associated with RV index RV=j (where j is an integer between 1 and K, inclusive), when applied to the TB 402, results in a subblock combination where each row of subblocks is shifted according to the computation (j−1)*(i−1)mod K. However, because K=M and M is not a prime number, it is expected that there will be overlapping of columns among the subblock combinations. To reduce the amount of column overlap, the RV index skipping technique defines the group of subblock interleaver sets such that the subblock interleaver sets in the group are only associated with RV index values where, for RV=j, the greater common factor between (j−1) and K is 1 (i.e., (j−1) and K are coprime). Any RV index that does not satisfy this coprime requirement is skipped, meaning there is no subblock interleaver set defined for that RV index. The RV index that is skipped in this manner may not be used for any retransmission, since there is no subblock interleaver set defined for that RV index. Alternatively, to preserve the use of consecutive RV indices in retransmissions, the subblock interleaver sets, after being defined using the RV index skipping technique, may be re-assigned to consecutive RV indices. For example, if subblock interleaver sets are defined for RV indices 1, 2 and 4 and RV index RV=3 is skipped, then after the subblock interleaver sets have been defined they may be re-assigned to RV indices 1, 2 and 3 (i.e., the subblock interleaver set that was defined using RV=4 is re-assigned to the RV index RV=3).

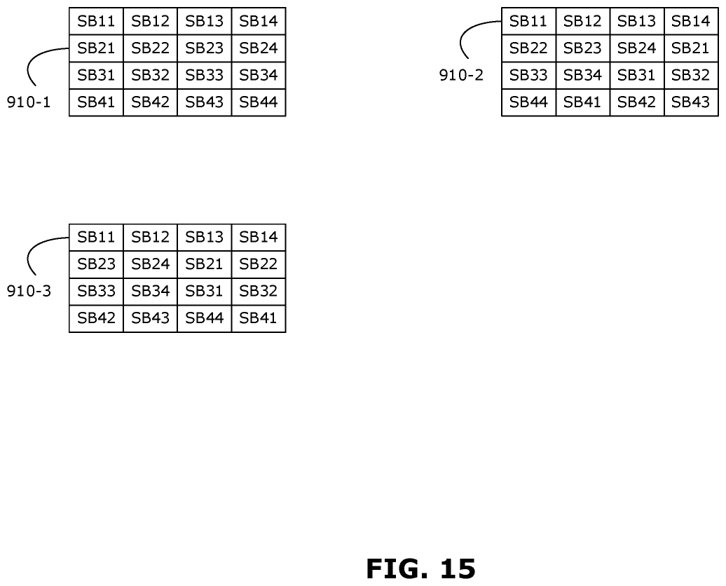

FIG. 15 illustrates an example using the RV index skipping technique to define the group of subblock interleaver sets, in which the number of information CBs 410 is four (M=4). Hence, the number of subblocks per information CB 410 is also four (K=4). It should be noted that in this example, the RV index RV=3 is skipped, since the numbers (j−1)=(3−1)=2 and K=4 are not coprime.

The cyclic shift in each row of the subblock combinations 910-1 to 910-3 in the example of FIG. 15 are as follows:

| | j = 1 | j = 2 | j = 4 |
|---|---|---|---|
| i = 1 | 0 | 0 | 0 |
| i = 2 | 0 | 1 | 3 |
| i = 3 | 0 | 2 | 2 |
| i = 4 | 0 | 3 | 1 |

where j denotes the RV index (i.e., RV = 1, RV = 2, and RV = 4), and i denotes the row of subblocks.

Thus, the subblock combinations 910-1, 910-2 and 910-3 shown in FIG. 15 correspond to the subblock interleaver sets defined using RV indices RV=1, RV=2 and RV=4, respectively (skipping the RV index RV=3). However, the subblock interleaver set defined using RV=4 may be reassigned to RV index RV=3 in order to use consecutive RV indices for retransmissions.

The above discussions have described definitions for a group of subblock interleaver sets that can be used to generate vertical check blocks for K RVs, where K is defined to be equal to the number of information CBs in the TB or is the minimum prime number equal to or greater than the number of information CBs. However, in some situations (e.g., where there is a high amount of noise in the wireless communication channel), a greater number of retransmissions may be required. In some cases, additional retransmissions (i.e., retransmissions that take place after K retransmissions) may simply reuse RV indices, with the result that the same subblock interleaver set may be used to generate vertical check blocks for more than one retransmission (e.g., the same subblock interleaver may be associated with RV indices RV=1 and RV=(K+1) or two different retransmissions may use the same RV indices). Such reuse of subblock interleaver sets is considered to be within the scope of the disclosure.

The present disclosure also describes example techniques for defining additional subblock interleaver sets, so that there is no reuse of subblock interleaver sets for more than one retransmission. This may help to provide performance gain, compared to retransmission schemes that reuse subblock interleaver sets.

The following techniques for defining additional subblock interleaver sets may result in some overlapping of columns in different subblock combinations. However, the amount of overlap is expected to be relatively low. Further, even with some overlapping of columns, defining additional subblock interleaver sets using the techniques described below still provides performance gains compared to reuse of subblock interleaver sets.

In some examples, additional subblock interleaver sets may be defined by increasing the number of subblocks per information CB. For example, if there are five information CBs (i.e., M=5), instead of dividing each information CB into five subblocks, the number of subblocks per information CB may be selected to be the next higher prime number (K=7). This would enable seven unique subblock interleaver sets to be defined for performing seven retransmissions using seven different RV indices (i.e., without repeating a subblock interleaver set in the seven retransmission), instead of five retransmissions (which would require two subblock interleaver sets to be reused; or would require one subblock interleaver set to be reused twice). This approach may be used if it is known or expected that a greater number of retransmissions would be needed (e.g., if it is known that the wireless communication channel is noisy).

In some examples, the prime number-based cyclic shifting technique may be first used to define a group subblock interleaver sets for a first prime number of RVs, which is then used for the first prime number of retransmission. Then, if additional retransmissions are needed after the first prime number of retransmissions have been performed, the number of subblocks per information CB can be increased to a second prime number (e.g., the next higher prime number after the first prime number), in order to define an additional group of subblock interleaver sets for additional retransmissions.

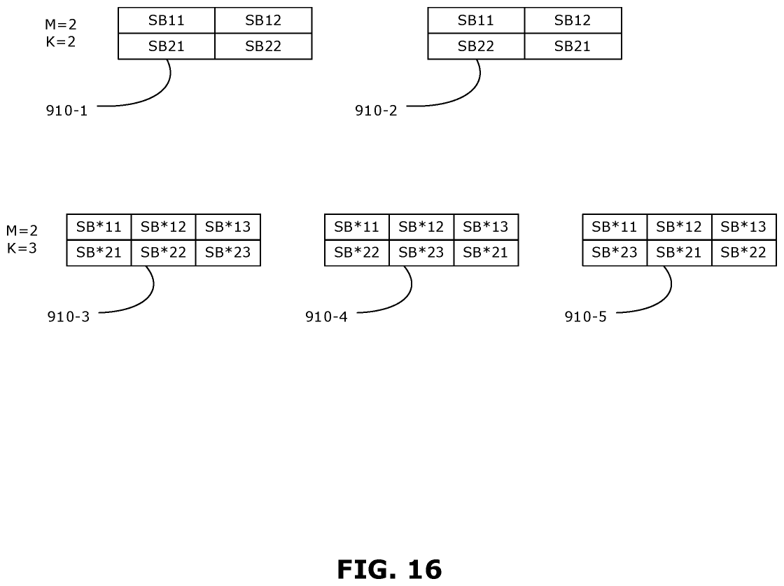

FIG. 16 illustrates an example in which additional retransmissions are performed by using additional subblock interleaver sets that increase the number of subblocks per information CB to a next higher prime number.

In this example, there are two information CBs, thus using the prime number-based cyclic shifting technique a group of two subblock interleaver sets is defined (i.e., M=K=2). As shown in FIG. 16, a first subblock combination 910-1 is used to generate vertical check blocks for a first retransmission, and a second subblock combination 910-2 is used to generate vertical check blocks for a second retransmission.

If additional retransmissions are needed, the number of subblocks per information CB is increased to the next higher prime number. In FIG. 16, the notation SB* denotes subblocks that result from splitting each information CB into the next higher prime number of subblocks (in this case, K=3). Then, the prime number-based cyclic shifting technique may be repeated for an additional group of three subblock interleaver sets, resulting in a third, fourth and fifth subblock combination 910-3, 910-4 and 910-5 that can be used to generate vertical check blocks for three additional retransmissions.

In another example, additional subblock interleaver sets may be defined by first defining an alternate base subblock combination that is different from the natural order of the subblocks in the initial transmission. Notably, the alternate base subblock combination is not the result of cyclic shifting of the natural order of subblocks, but rather is the result of applying a non-cyclic shift shuffling or permutation to at least one row of subblocks.

For example, the order of subblocks in one or more rows may be reversed to create the alternate base subblock combination.

In another example, a bit interleaver may be used to shuffle the bits (rather than the subblocks) of one or more rows to create the alternate base subblock combination.

In another example, the bits of one or more rows may be cyclic-shifted by an amount that is smaller than the size of a subblock defined by the subblock interleaver set (e.g., if the subblock interleaver set defines a subblock as having 1024 bits, a cyclic shift of 512 bits may be applied to one or more rows) to create the alternate base subblock combination.

Regardless of the technique used to create the alternate base subblock combination, after the alternate base subblock combination has been created, the previously described prime number-based cyclic shifting or dual subblock-based cyclic shifting techniques may be used to define an additional group of subblock interleaver sets from the alternate base subblock combination. The technique(s) used for creating the alternate base subblock combination may be predefined (e.g., defined in a standard) and known to both the transmitting node and the receiving node.

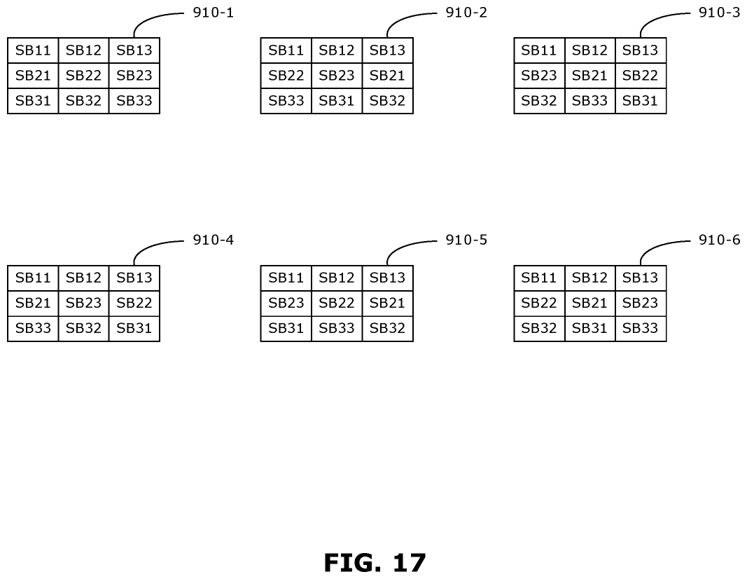

FIG. 17 illustrates an example in which additional retransmissions are performed by creating an alternate base subblock combination by switching the order of subblocks in one or more rows.

In this example, there are three information CBs, thus using the prime number-based cyclic shifting technique a group of three subblock interleaver sets are defined (i.e., M=K=3). As shown in FIG. 17, subblock combinations 910-1 to 910-3 are obtained using subblock interleaver sets that have been defined using the prime number-based cyclic shifting technique and applied to the natural order of the subblocks in the TB. After the first prime number of retransmissions have been performed, if additional retransmissions are required an alternate subblock combination is created (e.g., by switching two subblocks within a row, or by reversing the order of subblocks in a row).

In the example of FIG. 17, an alternate subblock combination 910-4 is created, for which the first row is the same as subblock combinations 910-1 to 910-3, and the second and third rows are obtained by applying non-cyclic shift based subblock interleavers to the corresponding rows in subblock combination 910-1. Then a further two subblock combinations 910-5 and 910-6 are obtained by applying another group of subblock interleaver sets (e.g., defined using prime number-based cyclic shifting) to the alternate subblock combination 910-4. The additional subblock combinations 910-4 to 910-6 can be used to generate vertical check blocks for three additional retransmissions.

In this example, the first row of subblocks is kept unchanged in all subblock combinations 910-1 to 910-6, to be used as a reference row. However, this is not intended to be limiting, and any other row may be used as a reference row instead. It may be noted that there are no overlapping columns among the subblock combinations 910-1 to 910-3; and there are no overlapping columns among subblock combinations 910-4 to 910-6. However, it cannot be guaranteed that there are no overlapping columns among all six subblock combinations 910-1 to 910-6 together.

FIG. 17 illustrates an example in which an additional group of subblock interleaver sets is defined from the alternate base subblock combination using the prime number-based cyclic shifting technique; however it should be understood that the dual subblock-based cyclic shifting technique may be used instead.

In various examples, the present disclosure has described methods and systems for performing retransmissions using vertical check blocks, in which the vertical check blocks generated for a given retransmission is generated using a subblock interleaver set that is associated with the RV index of the given retransmission. Each subblock interleaver set is uniquely associated with a respective RV index (i.e., there is no subblock interleaver set that is associated with more than one RV index). In this way, the transmitting node and the receiving node both can determine the subblock interleaver set that is used for a given retransmission if the RV index is known, and only the RV index for the given retransmission needs to be signaled. The disclosed retransmission schemes include feedback-based retransmission schemes as well as blind retransmission or repetition schemes.

Although we have described the subblock interleaver set being associated with an RV index, it should be understood that the subblock interleaver set may be associated with some other index or parameter. For example, instead of using the RV index as the basis for determining which subblock interleaver set to use for generating the vertical check blocks for a given retransmission, an interleaver index or interleaver parameter may be introduced in the signaling, which may be used to uniquely identify the subblock interleaver set (e.g., each subblock interleaver set may be uniquely associated with a respective interleaver index value or interleaver parameter value). Then, the interleaver index or interleaver parameter (or some other index that is uniquely associated with the subblock interleaver set) may be communicated (in addition to the RV index) to the receiving node to enable the receiving node to identify the subblock interleaver set that is used for a given retransmission. In such examples, the function of the RV index may be the same as in conventional HARQ retransmission schemes. That is, the RV index may correspond to different starting positions of the circular buffer of the channel coding used to generate vertical check blocks. Selecting different RV index values corresponds to selecting different sets of coded bits (from the same set of information bits) for generating the vertical check blocks.

It may be noted that the design of subblock interleaver sets, as disclosed herein, may still be applicable if an interleaver index or interleaver parameter (or some other index that is uniquely associated with the subblock interleaver set) is associated with the subblock interleaver set instead of the RV index. For example, in the formulas described herein, the variable j may represent the interleaver index or interleaver parameter instead of the RV index.

In examples where the RV index is used to indicate the subblock interleaver set that is used to generate the vertical check blocks, the location of the set of coded bits (or the starting position of the circular buffer) selected from the information bits to generate VCBs may be fixed or predefined.

The present disclosure describes different techniques for defining a group of subblock interleaver sets that can be used for a defined number of RV indices. In particular, the present disclosure describes a technique, referred to as prime number-based cyclic shifting, that aims to maximize the usefulness of information carried in the vertical check blocks (and hence maximize the performance of the wireless communication system).

The present disclosure also describes techniques for defining additional groups subblock interleaver sets, in the event that additional retransmissions are needed.

Although the present disclosure describes methods and processes with steps in a certain order, one or more steps of the methods and processes may be omitted or altered as appropriate. One or more steps may take place in an order other than that in which they are described, as appropriate.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein. The machine-executable instructions may be in the form of code sequences, configuration information, or other data, which, when executed, cause a machine (e.g., a processor or other processing device) to perform steps in a method according to examples of the present disclosure.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

1. A method, comprising:
performing an initial transmission, including transmitting a transport block comprising two or more information code blocks (CBs) to a receiving node;
performing a first retransmission to the receiving node, including transmitting at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and
performing a second retransmission to the receiving node, including transmitting at least one check block from a second set of one or more check blocks generated using a second subblock interleaver set associated with a second RV index of the second retransmission.

2. The method of claim 1, further comprising:
prior to performing the initial transmission, providing to the receiving node an RV index of the initial transmission; and
providing the first RV index of the first retransmission and the second RV index of the second retransmission to the receiving node prior to performing the first retransmission and prior to performing the second retransmission, respectively.

3. The method of claim 2, wherein the RV index of the initial transmission, the first RV index of the first retransmission and the second RV index of the second retransmission are provided together in a control signal or configuration signal to the receiving node prior to performing the initial transmission.

4. The method of claim 1,
wherein feedback from the receiving node indicates whether the receiving node successfully decoded the two or more information CBS;
the method further comprising:
performing the first retransmission after determining, from received negative acknowledgement (NACK) feedback or absence of acknowledgement (ACK) feedback, that the receiving node failed to successfully decode the two or more information CBs after the initial transmission; and
performing the second retransmission after determining, from received NACK feedback or absence of ACK feedback, that the receiving node failed to successfully decode the two or more information CBs after the first retransmission.

5. The method of claim 1, wherein a predetermined number of retransmissions, including the first and second retransmissions, is performed without requiring any feedback from the receiving node.

6. An apparatus comprising a processing unit, the processing unit being configured to execute machine-readable instructions to cause the apparatus to carry out a method comprising:
performing an initial transmission, including transmitting a transport block comprising two or more information code blocks (CBs) to a receiving node;
performing a first retransmission to the receiving node, including transmitting at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and
performing a second retransmission to the receiving node, including transmitting at least one check block from a second set of one or more check blocks generated using a second subblock interleaver set associated with a second RV index of the second retransmission.

7. The apparatus of claim 6, wherein the processing unit causes the apparatus to carry out the method further comprising:
prior to performing the initial transmission, providing to the receiving node an RV index of the initial transmission; and
providing the first RV index of the first retransmission and the second RV index of the second retransmission to the receiving node prior to performing the first retransmission and prior to performing the second retransmission, respectively.

8. The apparatus of claim 7, wherein the RV index of the initial transmission, the first RV index of the first retransmission and the second RV index of the second retransmission are provided together in a control signal or configuration signal to the receiving node prior to performing the initial transmission.

9. The apparatus of claim 6,
wherein feedback from the receiving node indicates whether the receiving node successfully decoded the two or more information CBS;
wherein the processing unit causes the apparatus to carry out the method further comprising:
performing the first retransmission after determining, from received negative acknowledgement (NACK) feedback or absence of acknowledgement (ACK) feedback, that the receiving node failed to successfully decode the two or more information CBs after the initial transmission; and
performing the second retransmission after determining, from received NACK feedback or absence of ACK feedback, that the receiving node failed to successfully decode the two or more information CBs after the first retransmission.

10. The apparatus of claim 6, wherein a predetermined number of retransmissions, including the first and second retransmissions, is performed without requiring any feedback from the receiving node.

11. A method, comprising:
receiving an initial transmission from a transmitting node, including a transport block comprising two or more information code blocks (CBs);
receiving a first retransmission from the transmitting node, including at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and
receiving a second retransmission from the transmitting node, including at least one check block from a second set of one or more check blocks generated using a second subblock interleaver set associated with a second RV index of the second retransmission.

12. The method of claim 11, further comprising:
prior to receiving the initial transmission, receiving an RV index of the initial transmission;
receiving the first RV index of the first retransmission and the second RV index of the second retransmission prior to receiving the first retransmission and prior to receiving the second retransmission, respectively; and
determining the first subblock interleaver set and the second subblock interleaver set using the first RV index and the second RV index, respectively.

13. The method of claim 12, wherein the RV index of the initial transmission, the first RV index of the first retransmission and the second RV index of the second retransmission are received together in a control signal or configuration signal prior to receiving the initial transmission.

14. The method of claim 11, further comprising:
after the initial transmission, transmitting to the transmitting node a first indicator that the two or more information CBs were not all successfully decoded, wherein the first retransmission is received subsequent to transmitting the first indicator; and
after the first retransmission, transmitting to the transmitting node a second indicator that the two or more information CBs were not all successfully decoded, wherein the second retransmission is received subsequent to transmitting the second indicator.

15. The method of claim 11, wherein a predetermined number of retransmissions, including the first and second retransmissions, is scheduled.

16. An apparatus comprising a processing unit, the processing unit being configured to execute machine-readable instructions to cause the apparatus to carry out a method comprising:
receiving an initial transmission from a transmitting node, including a transport block comprising two or more information code blocks (CBs);
receiving a first retransmission from the transmitting node, including at least one check block from a first set of one or more check blocks, the at least one check block generated from at least part of each of the two or more information CBs, the first set of one or more check blocks generated using a first subblock interleaver set associated with a first redundancy version (RV) index of the first retransmission; and
receiving a second retransmission from the transmitting node, including at least one check block from a second set of one or more check blocks generated using a second subblock interleaver set associated with a second RV index of the second retransmission.

17. The apparatus of claim 16, wherein the processing unit causes the apparatus to carry out the method further comprising:
prior to receiving the initial transmission, receiving an RV index of the initial transmission;
receiving the first RV index of the first retransmission and the second RV index of the second retransmission prior to receiving the first retransmission and prior to receiving the second retransmission, respectively; and
determining the first subblock interleaver set and the second subblock interleaver set using the first RV index and the second RV index, respectively.

18. The apparatus of claim 17, wherein the RV index of the initial transmission, the first RV index of the first retransmission and the second RV index of the second retransmission are received together in a control signal or configuration signal prior to receiving the initial transmission.

19. The apparatus of claim 16, wherein the processing unit causes the apparatus to carry out the method further comprising:
after the initial transmission, transmitting to the transmitting node a first indicator that the two or more information CBs were not all successfully decoded, wherein the first retransmission is received subsequent to transmitting the first indicator; and
after the first retransmission, transmitting to the transmitting node a second indicator that the two or more information CBs were not all successfully decoded, wherein the second retransmission is received subsequent to transmitting the second indicator.

20. The apparatus of claim 16, wherein a predetermined number of retransmissions, including the first and second retransmissions, is scheduled.
